(19) United States
(12) Patent Application Publication
(10) Pub. No.: US 2026/0164781 A1
(43) Pub. Date: Jun. 11, 2026

(54) METAL CONTACT AIR-GAP FORMATION PROCESS AND METHOD

(71) Applicant: Taiwan Semiconductor Manufacturing Co., Ltd., Hsinchu (TW)

(72) Inventors: Yung-Ting Chang, New Taipei (TW); Jui-Lin Chen, Taipei (TW)

(21) Appl. No.: 18/973,638

(22) Filed: Dec. 9, 2024

(51) Int. Cl. H10D 84/85; H10B 10/00; H10D 30/00; H10D 30/01; H10D 30/67; H10D 62/10; H10D 64/01; H10D 84/01

(52) U.S. Cl. CPC H10D 84/851; H10B 10/125; H10D 30/014; H10D 30/0191; H10D 30/502; H10D 30/6729; H10D 30/6735; H10D 62/121; H10D 64/021; H10D 84/0167; H10D 84/017

(57) ABSTRACT

In an embodiment, a semiconductor device includes a plurality of first nanostructures, the plurality of first nanostructures extending between first source/drain regions, a plurality of second nanostructures over the plurality of first nanostructures, the plurality of second nanostructures extending between second source/drain regions, a first gate stack around the plurality of first nanostructures, a second gate stack over the first gate stack and disposed around the plurality of second nanostructures, where a first portion of the second gate stack is disposed above the plurality of second nanostructures, gate spacers on sidewalls of the first portion of the second gate stack, and a first metal contact that is in physical contact with a first source/drain region of the second source/drain regions, where an air-gap is disposed between a sidewall of the first metal contact and a sidewall of a first gate spacer of the gate spacers.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example schematic of a stacked transistor, such as a complementary field-effect transistor (CFET), in a three-dimensional view, in accordance with some embodiments.

FIGS. 2-25D are views of intermediate stages in the manufacturing of CFETs, in accordance with some embodiments.

FIG. 26 is a view of an intermediate stage in the manufacturing of CFETs, in accordance with other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, CFETs are formed. A CFET includes a lower nanostructure-FET and an upper nanostructure-FET. For example, in an embodiment, the CFET may be configured as part of a Static Random Memory (SRAM) cell, the CFET including an n-type nanostructure-FET (e.g., the upper nanostructure-FET) in a NMOS (N-channel Metal-Oxide-Semiconductor) portion of the CFET and a p-type nanostructure-FET (e.g., the lower nanostructure-FET) in a PMOS (P-channel Metal-Oxide-Semiconductor) portion of the CFET. The NMOS portions of the CFETs may be disposed in a region of the SRAM cell that may be referred to subsequently as the NMOS portion of the SRAM cell. The PMOS portions of the CFETs may be disposed in a region of the SRAM cell that may be referred to subsequently as the PMOS portion of the SRAM cell. In an embodiment, an air-gap may be formed to surround a bit line contact (e.g., which is electrically connected to a bit line) in a bit line region of the NMOS portion of the SRAM cell. However, no air-gap is formed to surround a first node contact (e.g., which is electrically connected to an internal storage node) in a node region of the NMOS portion of the SRAM cell, and no air-gap is formed to surround a voltage source supply (VSS) contact (e.g., which may be electrically connected to sources of NMOS portions of the CFETs) in a first region of the NMOS portion of the SRAM cell. The air-gap may be formed by first depositing a sacrificial silicon layer. The sacrificial silicon layer is then selectively removed to leave a space where the sacrificial silicon layer was previously disposed. In addition, an air-gap may be formed to surround a second node contact (e.g., which may be electrically connected to the internal storage node) in a node region of the PMOS portion of the SRAM cell, and an air-gap may be formed to surround a voltage drain supply (VDD) contact (e.g., which may be electrically connected to sources of PMOS portions of the CFETs) in a first region of the PMOS portion of the SRAM cell.

Advantageous features of one or more embodiments disclosed herein may allow for a reduction of the capacitance associated with the bit line contact. As a result, total capacitance of the bit line of the SRAM cell can be reduced, and less charge may be required to change the bit line voltage during read and write operations. This leads to quicker read and write operations in the SRAM cell. As a result, the speed of the SRAM cell operations can be increased. In addition, due to no air-gap being formed to surround each of the first node contact and the VSS contact in the NMOS portion of the SRAM cell, the VSS contact and the first node contact can be formed having larger dimensions (e.g., larger widths) as there is no need to accommodate the space that would be occupied by the air-gap. The increased dimensions of the first node contact and the VSS contact lead to lower electrical resistances through these contacts, and as a result, SRAM cell performance can be improved. Further, by selectively adding air-gaps to surround each of the second node contact and the VDD contact in the PMOS portion of the SRAM cell, an improved match can be achieved between the device performance of the n-type nanostructure-FET in the NMOS portion of the CFET and the device performance of the p-type nanostructure-FET in the PMOS portion of the CFET.

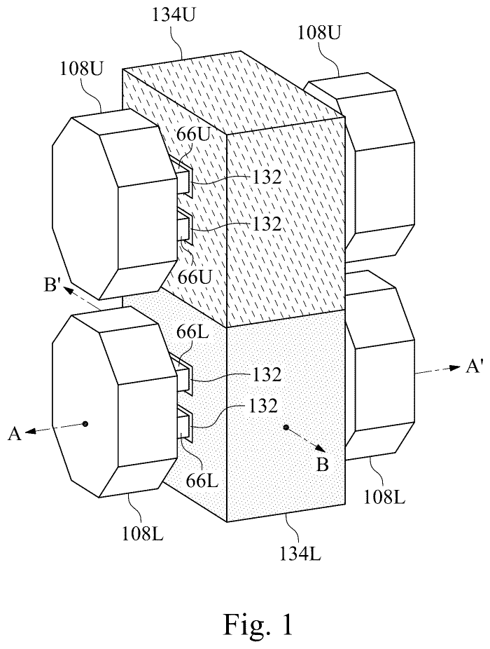

FIG. 1 illustrates an example schematic of a stacked transistor, such as a complementary field-effect transistor (CFET), in accordance with some embodiments. FIG. 1 is a three-dimensional view, where some features of the CFETs are omitted for illustration clarity.

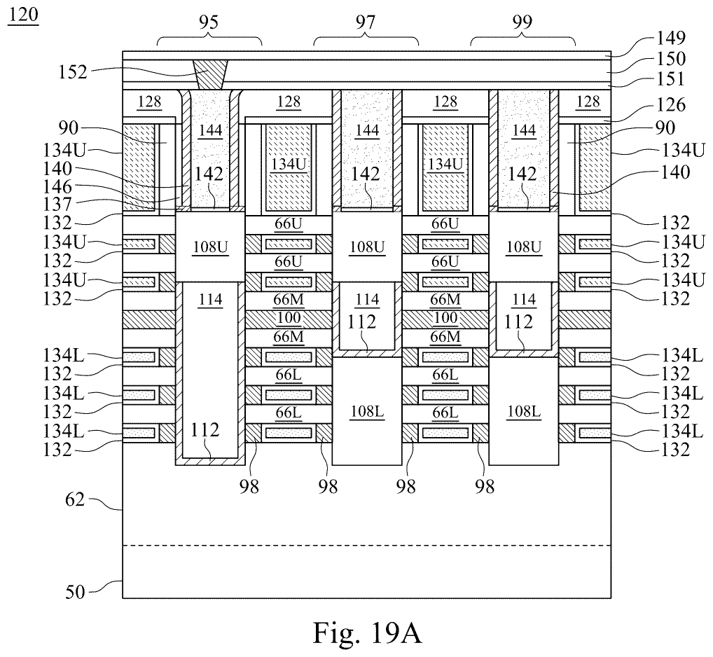

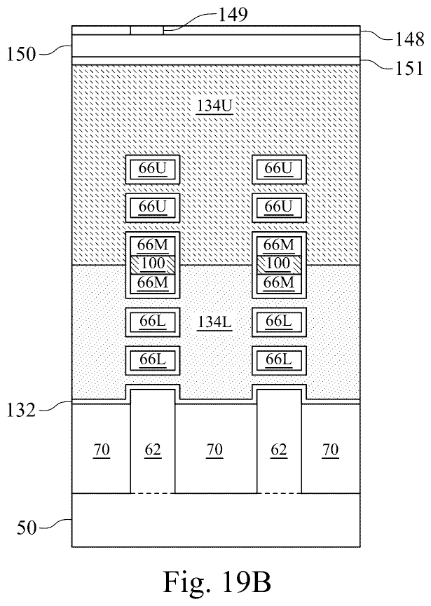

The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures 66 (including lower semiconductor nanostructures 66L and upper semiconductor nanostructures 66U), where the semiconductor nanostructures 66 act as channel regions for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A channel isolation material (not explicitly illustrated in FIG. 1, see FIGS. 19A-19B) may be used to separate and electrically isolate the upper semiconductor nanostructures 66U from the lower semiconductor nanostructures 66L.

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. Source/drain regions 108 (including lower epitaxial source/drain regions 108L and upper epitaxial source/drain regions 108U) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U. Alternatively, a lower gate electrode 134L may be coupled to an upper gate electrode 134U. Further, the upper epitaxial source/drain regions 108U may be separated from lower epitaxial source/drain regions 108L by one or more dielectric layers (not explicitly illustrated in FIG. 1, see FIGS. 19A-19B). The isolation features between channel regions, gates, and source/drain regions allow for vertically stacked transistors, thereby improving device density. Because of the vertically stacked nature of CFETs, the schematic may also be referred to as stacked transistors or folding transistors.

FIG. 1 further illustrates reference cross-sections that are used in later figures. Cross-section A-A′ is parallel to a longitudinal axis of the semiconductor nanostructures 66 of a CFET and in a direction of, for example, a current flow between the source/drain regions 108 of the CFET. Cross-section B-B′ is perpendicular to cross-section A-A′ and along a longitudinal axis of a gate electrode 134 of a CFET. Subsequent figures refer to these reference cross-sections for clarity.

Some embodiments discussed herein are discussed in the context of CFETs. Other embodiments may contemplate aspects used in nanostructure-FETs (e.g., nanowire FETs, nanosheet FETs, multi bridge channel (MBC) FETs, nanoribbon FETs, gate-all-around (GAA) FETs, or the like).

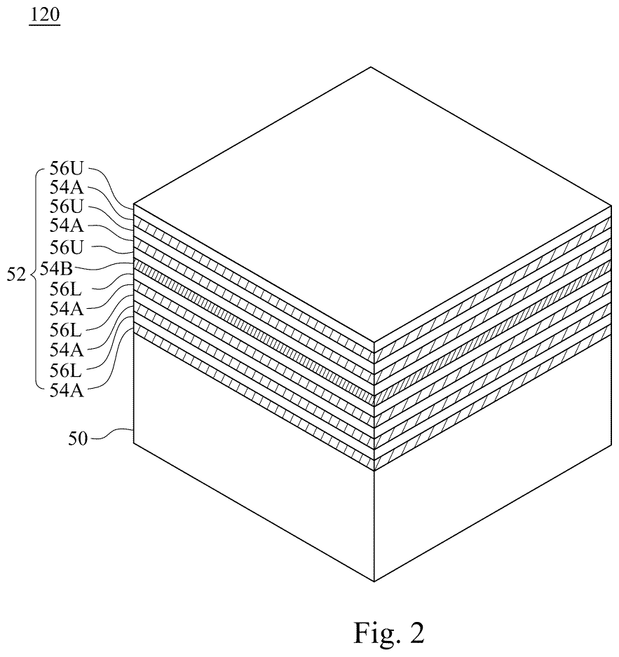

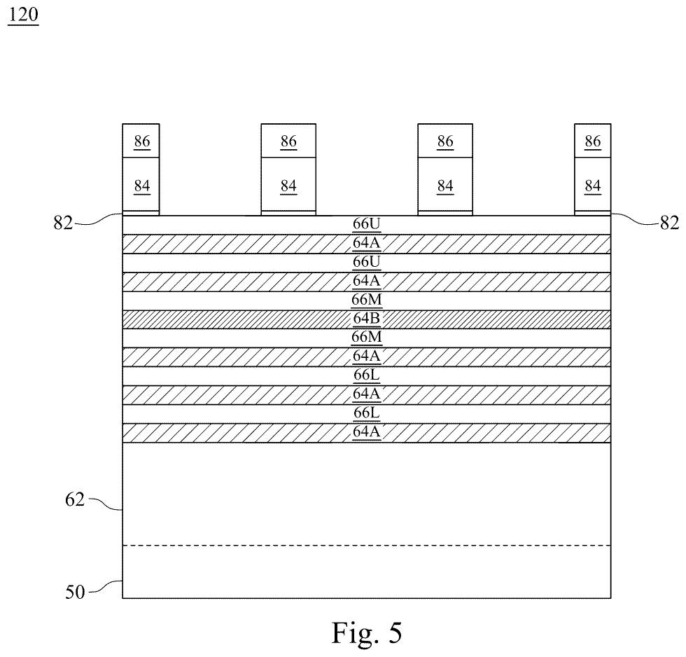

FIGS. 2-26 are views of intermediate stages in the manufacturing of a semiconductor device 120 that includes CFETs, in accordance with some embodiments. FIGS. 2, 3, and 4 are three-dimensional views showing a similar three-dimensional view as FIG. 1. FIGS. 5, 6, 7, 8, 9, 10, 11, 12, 13, 14, 15, 16, 17, 18A, 18B, 19A, 20, 21, 22, 23, 24, 25A, and 26 illustrate cross-sectional views along a similar cross-section as reference cross-section A-A′ in FIG. 1. FIG. 19B illustrates a cross-sectional view along a similar cross-section as reference cross-section B-B′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 52 is formed over the substrate 50. The multi-layer stack 52 includes alternating dummy layers 54 (including first dummy layers 54A and a second dummy layer 54B) and semiconductor layers 56 (including lower semiconductor layers 56L and upper semiconductor layers 56U). The lower semiconductor layers 56L and a subset of the first dummy layers 54A are disposed below the second dummy layer 54B. The upper semiconductor layers 56U and another subset of the first dummy layers 54A are disposed above the second dummy layer 54B. As subsequently described in greater detail, the dummy layers 54 will be removed and the semiconductor layers 56 will be patterned to form channel regions of CFETs. Specifically, the lower semiconductor layers 56L will be patterned to form channel regions of the lower nanostructure-FETs of the CFETs, and the upper semiconductor layers 56U will be patterned to form channel regions of the upper nanostructure-FETs of the CFETs.

The multi-layer stack 52 is illustrated as including a specific number of the dummy layers 54 and a specific number of the semiconductor layers 56. It should be appreciated that the multi-layer stack 52 may include any number of the dummy layers 54 and the semiconductor layers 56. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first dummy layers 54A are formed of a first semiconductor material, and the second dummy layer 54B is formed of a second semiconductor material. The first and second semiconductor materials may be selected from the candidate semiconductor materials of the substrate 50. The semiconductor materials of the first dummy layers 54A and the second dummy layer 54B will be subsequently described in greater detail. The first and second semiconductor materials have a high etching selectivity to one another. As such, the material of the second dummy layer 54B may be removed at a faster rate than the material of the first dummy layers 54A in subsequent processing.

The semiconductor layers 56 (including the lower semiconductor layers 56L and upper semiconductor layers 56U) are formed of one or more semiconductor material(s). The semiconductor material(s) may be selected from the candidate semiconductor materials of the substrate 50. The lower semiconductor layers 56L and the upper semiconductor layers 56U may be formed of the same semiconductor material, or may be formed of different semiconductor materials. In some embodiments, the lower semiconductor layers 56L and the upper semiconductor layers 56U are both be formed of a semiconductor material suitable for p-type devices and n-type devices, such as silicon. In some embodiments, the lower semiconductor layers 56L are formed of a semiconductor material suitable for p-type devices, such as germanium or silicon-germanium, and the upper semiconductor layers 56U are formed of a semiconductor material suitable for n-type devices, such as silicon or carbon-doped silicon. The semiconductor material(s) of the semiconductor layers 56 will be subsequently described in greater detail. The semiconductor material(s) of the semiconductor layers 56 have a high etching selectivity to the semiconductor materials of the dummy layers 54. As such, the materials of the dummy layers 54 may be removed at a faster rate than the material of the semiconductor layers 56 in subsequent processing.

Some layers of the multi-layer stack 52 may be thicker than other layers of the multi-layer stack 52. The thickness of the second dummy layer 54B may be different (e.g., greater or less) than the thickness of each of the first dummy layers 54A. In some embodiments, the second dummy layer 54B has a small thickness, such as a lesser thickness than each of the first dummy layers 54A. In other embodiments, the second dummy layer 54B has a large thickness, such as a greater thickness than each of the first dummy layers 54A. Additionally, the thickness of each of the semiconductor layers 56 may be different (e.g., greater or less) than the thickness(es) of each of the first dummy layers 54A and/or the second dummy layer 54B. In some embodiments, the second dummy layer 54B may be thicker than each of the semiconductor layers 56. In other embodiments, each of the semiconductor layers 56 may be thicker than each of the dummy layers 54.

In some embodiments, the first dummy layers 54A are formed of silicon-germanium, the second dummy layer 54B is formed of doped silicon, and the semiconductor layers 56 are formed of silicon. The silicon of the semiconductor layers 56 may be undoped or lightly doped at this step of processing. In some embodiments, the second dummy layer 54B are formed of silicon doped with an n-type impurity or with a p-type impurity. The n-type impurity may be phosphorus, arsenic, or the like. The p-type impurity may be boron or the like. Utilizing doped silicon for the second dummy layer 54B allows it to have a high etching selectivity to the first dummy layers 54A and the semiconductor layers 56. For example, the second dummy layer 54B may be at least partially replaced with an isolation structure. As part of the replacement process, the second dummy layer 54B may be removed with an etchant that is selective to the dopant of the second dummy layer 54B. Accordingly, the second dummy layer 54B may be removed at a faster rate than the first dummy layers 54A and the semiconductor layers 56.

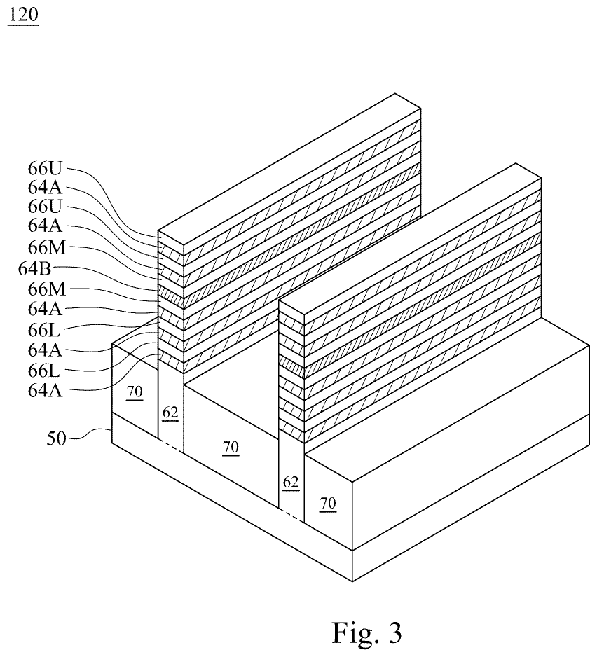

In FIG. 3, fins 62 are formed in the substrate 50 and nanostructures 64, 66 (including first dummy nanostructures 64A, second dummy nanostructures 64B, lower semiconductor nanostructures 66L, middle semiconductor nanostructures 66M, and upper semiconductor nanostructures 66U) are formed in the multi-layer stack 52. In some embodiments, the nanostructures 64, 66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 may define the first dummy nanostructures 64A from the first dummy layers 54A, the second dummy nanostructures 64B from the second dummy layer 54B, the lower semiconductor nanostructures 66L from some of the lower semiconductor layers 56L, the upper semiconductor nanostructures 66U from some of the upper semiconductor layers 56U, and the middle semiconductor nanostructures 66M from some of the lower semiconductor layers 56L and some of the upper semiconductor layers 56U. The first dummy nanostructures 64A and the second dummy nanostructures 64B may further be collectively referred to as the dummy nanostructures 64. The lower semiconductor nanostructures 66L and the upper semiconductor nanostructures 66U may further be collectively referred to as the semiconductor nanostructures 66.

As subsequently described in greater detail, various one of the nanostructures 64, 66 will be removed to form channel regions of CFETs. Specifically, the lower semiconductor nanostructures 66L will act as channel regions for lower nanostructure-FETs of the CFETs. Additionally, the upper semiconductor nanostructures 66U will act as channel regions for upper nanostructure-FETs of the CFETs.

The middle semiconductor nanostructures 66M are the semiconductor nanostructures 66 that are directly above/below (e.g., in contact with) the second dummy nanostructures 64B. Depending on the heights of subsequently formed source/drain regions, the middle semiconductor nanostructures 66M may or may not adjoin any source/drain regions and may or may not act as functional channel regions for the CFETs. The second dummy nanostructures 64B will be subsequently replaced with isolation structures. The isolation structures and the middle semiconductor nanostructures 66M may define boundaries of the lower nanostructure-FETs and the upper nanostructure-FETs.

The fins 62 and the nanostructures 64, 66 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64, 66. In some embodiments, a mask (or other layer) may remain on the nanostructures 64, 66.

Although each of the fins 62 and the nanostructures 64, 66 are illustrated as having a constant width throughout, in other embodiments, the fins 62 and/or the nanostructures 64, 66 may have tapered sidewalls such that a width of each of the fins 62 and/or the nanostructures 64, 66 continuously increases in a direction towards the substrate 50. In such embodiments, each of the nanostructures 64, 66 may have a different width and be trapezoidal in shape.

Further, isolation regions 70 are formed over the substrate 50 and between adjacent semiconductor fins 62. The isolation regions 70 may include a liner and a fill material over the liner. Each of the liner and the fill material may include a dielectric material such as an oxide (e.g., silicon oxide), a nitride (e.g., silicon nitride), the like, or a combination thereof. The formation of the isolation regions 70 may include depositing the dielectric material(s), and performing a planarization process such as a chemical mechanical polish (CMP) process, a mechanical polishing process, or the like to remove excess portions of the dielectric material(s), such as portions over the nanostructures 64, 66. The deposition processes may include ALD, high-density plasma chemical vapor deposition (HDP-CVD), flowable chemical vapor deposition (FCVD), the like, or a combination thereof. In some embodiments, the isolation regions 70 include silicon oxide formed by an FCVD process, followed by an anneal process. Then, the dielectric material(s) are recessed to define the isolation regions 70. The dielectric material(s) maybe recessed such that upper portions of the semiconductor fins 62 and the nanostructures 64, 66 extend higher than the isolation regions 70.

The previously described process is just one example of how the fins 62 and the nanostructures 64, 66 may be formed. In some embodiments, the fins 62 and/or the nanostructures 64, 66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64, 66. The epitaxial structures may comprise the previously described alternating semiconductor materials, such as the first semiconductor material, the second semiconductor material, and the doped silicon of the second dummy nanostructures 64B. In some embodiments where epitaxial structures are epitaxially grown, the epitaxially grown materials may be in situ doped during growth, which may obviate prior and/or subsequent implantations, although in situ and implantation doping may be used together.

In an embodiment, the semiconductor nanostructures 66 may have a lesser dopant concentration than the first dummy nanostructures 64A. In some embodiments, the first dummy nanostructures 64A have a dopant concentration of greater than 10²⁰ atoms/cm³, while the semiconductor nanostructures 66 have a dopant concentration in a range from 10¹⁷ atoms/cm³ to 10¹⁹ atoms/cm³. Therefore, a desired etching selectivity among the materials of the first dummy nanostructures 64A, the second dummy nanostructures 64B, and the semiconductor nanostructures 66 may still be achieved. Accordingly, and as subsequently described in greater detail, the first dummy nanostructures 64A may be removed at a faster rate than the second dummy nanostructures 64B and the semiconductor nanostructures 66.

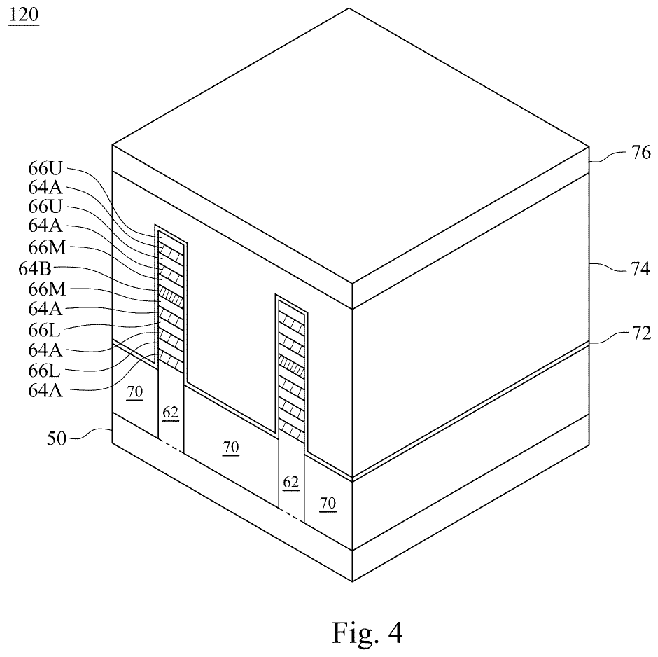

In FIG. 4, a dummy dielectric layer 72 is formed on the fins 62 and/or the nanostructures 64, 66. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 74 may be deposited by physical vapor deposition (PVD), CVD, sputter deposition, or other techniques for depositing the selected material. The dummy gate layer 74 may be formed of other materials that have a high etching selectivity to insulating materials. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the fins 62 and/or the nanostructures 64, 66.

In FIG. 5, the mask layer 76 may be patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

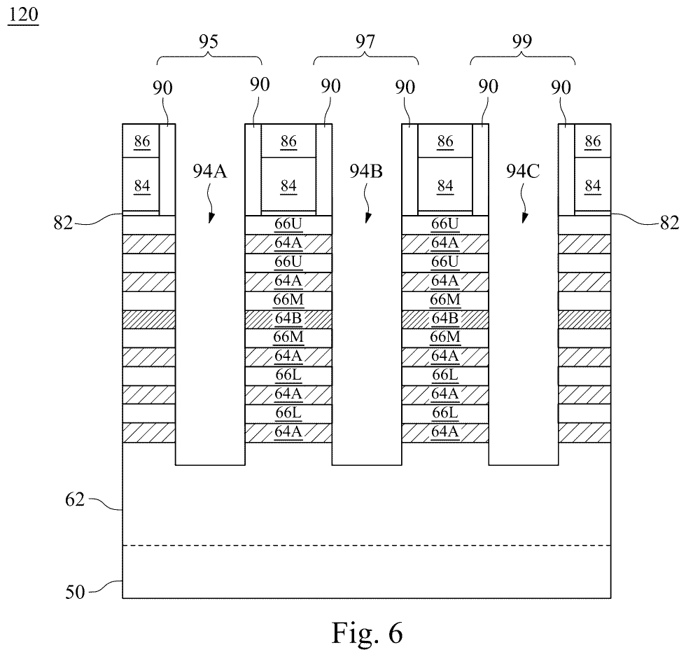

In FIG. 6, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 84 (thus forming the gate spacers 90). In some embodiments, the dielectric material(s), when etched, may also have portions left on the sidewalls of the fins 62 and/or the nanostructures 64, 66.

Further, implants for lightly doped source/drain (LDD) regions (not separately illustrated) may be performed. The LDD implants may be performed before the gate spacers 90 are formed. Appropriate type impurities may be implanted into the nanostructures 64, 66 to a desired depth. The LDD regions may have a same conductivity type as a conductivity type of source/drain regions that will be subsequently formed adjacent the semiconductor nanostructures 66. Additionally, the LDD regions in the lower semiconductor nanostructures 66L may have a conductivity type opposite from a conductivity type of the LDD regions in the upper semiconductor nanostructures 66U. In some embodiments, the lower semiconductor nanostructures 66L have p-type LDD regions and the upper semiconductor nanostructures 66U have n-type LDD regions. In some embodiments, the lower semiconductor nanostructures 66L have n-type LDD regions and the upper semiconductor nanostructures 66U have p-type LDD regions. The n-type impurities may be the any of the n-type impurities previously discussed, and the p-type impurities may be the any of the p-type impurities previously discussed. The lightly doped source/drain regions may have a concentration of impurities in a range from 10¹⁷ atoms/cm³ to 10²⁰ atoms/cm³. An anneal may be used to repair implant damage and to activate the implanted impurities. In some embodiments, the grown materials of the nanostructures 64, 66 may be in situ doped during growth, which may obviate the implantations, although in situ and implantation doping may be used together.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like.

Source/drain recesses 94 are formed in the fins 62, the nanostructures 64, 66, and the substrate 50. For example, a first source/drain recess 94A may be formed in the fins 62, the nanostructures 64, 66, and the substrate 50 in a first region 95 of the semiconductor device 120, a second source/drain recess 94B may be formed in the fins 62, the nanostructures 64, 66, and the substrate 50 in a second region 97 of the semiconductor device 120, and a third source/drain recess 94C may be formed in the fins 62, the nanostructures 64, 66, and the substrate 50 in a third region 99 of the semiconductor device 120. Epitaxial source/drain regions will be subsequently formed in the source/drain recesses 94. The source/drain recesses 94 may extend through the nanostructures 64, 66 and into the substrate 50. The fins 62 may be etched such that bottom surfaces of the source/drain recesses 94 are disposed above, below, or level with the top surfaces of the isolation regions 70. In the illustrated example, the top surfaces of the isolation regions 70 are above the bottom surfaces of the source/drain recesses 94. The source/drain recesses 94 may be formed by etching the fins 62, the nanostructures 64, 66, and the substrate 50 using anisotropic etching processes, such as RIE, NBE, or the like. The gate spacers 90 and the dummy gates 84 mask portions of the fins 62, the nanostructures 64, 66, and the substrate 50 during the etching processes used to form the source/drain recesses 94. A single etch process or multiple etch processes may be used to etch each layer of the nanostructures 64, 66 and/or the fins 62. Timed etch processes may be used to stop the etching of the source/drain recesses 94 after the source/drain recesses 94 reach a desired depth.

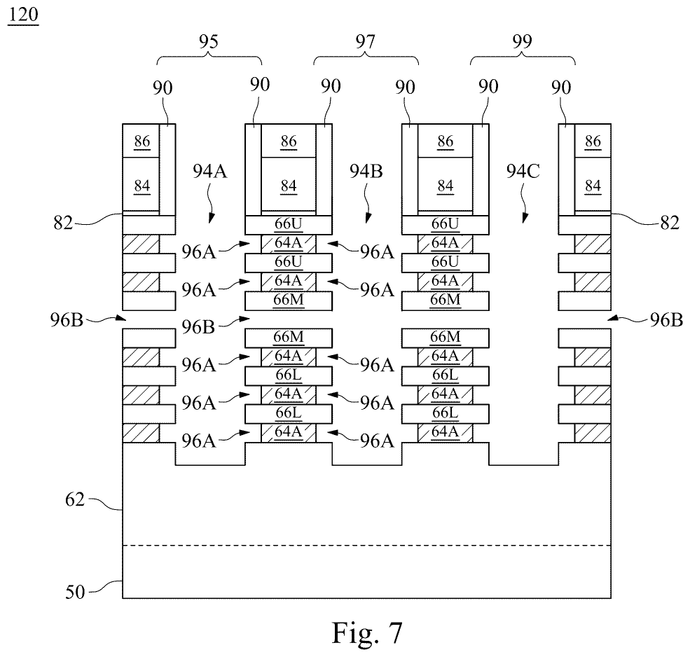

In FIG. 7, the sidewalls of the first dummy nanostructures 64A exposed by the source/drain recesses 94 are recessed to form sidewall recesses 96A. Additionally, the second dummy nanostructures 64B are removed to form openings 96B between the lower semiconductor nanostructures 66L (collectively) and the upper semiconductor nanostructures 66U (collectively). The sidewall recesses 96A will subsequently be filled with spacers. The openings 96B will subsequently be filled with isolation structures.

The sidewall recesses 96A may be formed by recessing the sidewalls of the first dummy nanostructures 64A with any acceptable etch process. The etching is selective to the first dummy nanostructures 64A (e.g., selectively etches the material of the first dummy nanostructures 64A at a faster rate than the material of the semiconductor nanostructures 66). The etching may be isotropic. Although sidewalls of the first dummy nanostructures 64A are illustrated as being straight after the etching, the sidewalls may be concave or convex.

The openings 96B may be formed by removing the second dummy nanostructures 64B with any acceptable etch process. The etching is selective to the second dummy nanostructures 64B (e.g., selectively etches the material of the second dummy nanostructures 64B at a faster rate than the material of the semiconductor nanostructures 66). The etching may be isotropic. The dummy gates 84 may adhere to and support the upper semiconductor nanostructures 66U so that the upper semiconductor nanostructures 66U do not collapse after the formation of the openings 96B.

In some embodiments, the same etching process is used to recess the sidewalls of the first dummy nanostructures 64A and to remove the second dummy nanostructures 64B. For example, the second dummy nanostructures 64B may be completely removed without completely removing the first dummy nanostructures 64A, and the first dummy nanostructures 64A may be recessed without significantly recessing the semiconductor nanostructures 66. The etching process has selectivity among the materials of the first dummy nanostructures 64A, the second dummy nanostructures 64B, and the semiconductor nanostructures 66. Specifically, the etching process selectively etches the material of the first dummy nanostructures 64A at a faster rate than the material of the semiconductor nanostructures 66, and also selectively etches the material of the second dummy nanostructures 64B at a faster rate than the selectively etches the material of the first dummy nanostructures 64A. Thus, the etch rate of the first dummy nanostructures 64A is less than the etch rate of the second dummy nanostructures 64B and is greater than the etch rate of the semiconductor nanostructures 66. In some embodiments where the first dummy nanostructures 64A are formed of silicon-germanium, the second dummy nanostructures 64B are formed of doped silicon with a high dopant concentration, and the semiconductor nanostructures 66 are formed of doped silicon with a low dopant concentration, the etch process is a dry etch using chlorine gas, with or without a plasma. The etch process etches the doped silicon with the high dopant concentration at a faster rate than the doped silicon with the low dopant concentration.

The middle semiconductor nanostructures 66M are exposed by the openings 96B. In some embodiments, the etching process thins the middle semiconductor nanostructures 66M. Accordingly, the thickness of the middle semiconductor nanostructures 66M may be different (e.g., less than) the thickness of the lower semiconductor nanostructures 66L and the thickness of the upper semiconductor nanostructures 66U. In some embodiments, the middle semiconductor nanostructures 66M are from 0% to 20% thinner than the lower semiconductor nanostructures 66L and the upper semiconductor nanostructures 66U after the etching process.

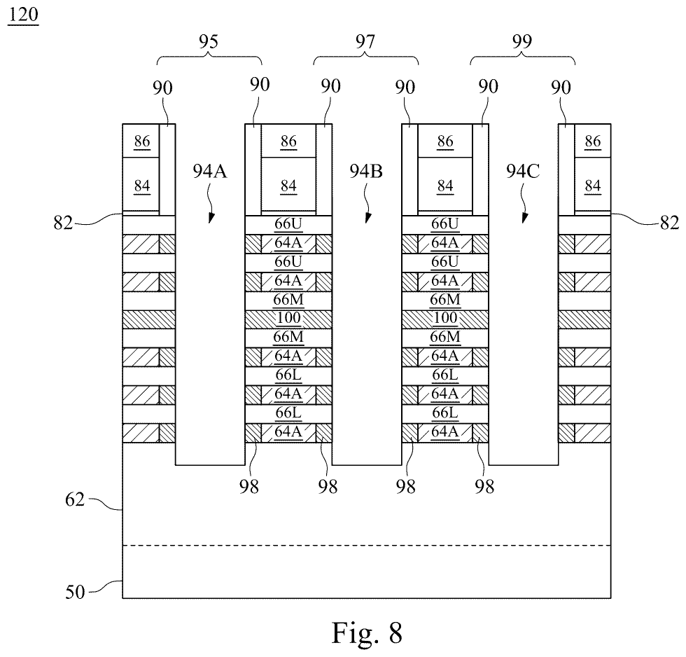

In FIG. 8, inner spacers 98 are formed in the sidewall recesses 96A and on the sidewalls of the remaining portions of the first dummy nanostructures 64A. As subsequently described in greater detail, source/drain regions will be subsequently formed in the source/drain recesses 94, and the first dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as etch processes used to form gate structures. Additionally, isolation structures 100 are formed in the openings 96B and between the middle semiconductor nanostructures 66M. The isolation structures 100 and the middle semiconductor nanostructures 66M will define the boundaries of the lower nanostructure-FETs and the upper nanostructure-FETs.

The inner spacers 98 and the isolation structures 100 may be formed by conformally forming an insulating material in the source/drain recesses 94, the sidewall recesses 96A, and the openings 96B, and then subsequently etching the insulating material. In an embodiment, the insulating material may be different from the dielectric material(s) of the gate spacers 90. The insulating material may be a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic. For example, the etch process may be a dry etch such as a RIE, a NBE, or the like. The insulating material, when etched, has portions remaining in the sidewall recesses 96A (thus forming the inner spacers 98) and has portions remaining in the openings 96B (thus forming the isolation structures 100).

Although outer sidewalls of the inner spacers 98 and the isolation structures 100 are illustrated as being flush with sidewalls of the semiconductor nanostructures 66, the outer sidewalls of the inner spacers 98 and the isolation structures 100 may extend beyond or be recessed from sidewalls of the semiconductor nanostructures 66. Thus, the inner spacers 98 and the isolation structures 100 may partially fill, completely fill, or overfill the sidewall recesses 96A and the openings 96B, respectively. Moreover, although the sidewalls of the inner spacers 98 and the isolation structures 100 are illustrated as being straight, those sidewalls may be concave or convex.

The isolation structures 100 have similar dimensions as the second dummy nanostructures 64B they replaced. Accordingly, the isolation structures 100 may have a large thickness, such as a greater thickness than the semiconductor nanostructures 66 and the first dummy nanostructures 64A, or the isolation structures 100 may have a small thickness, such as a lesser thickness than the semiconductor nanostructures 66 and the first dummy nanostructures 64A.

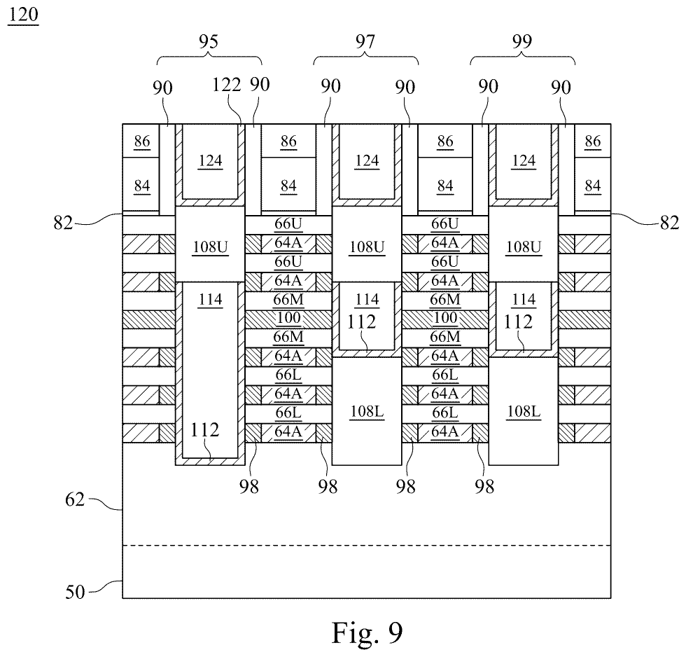

In FIG. 9, a suitable masking layer (e.g., a photoresist, a Bottom Anti-Reflective Coating (BARC) layer, or the like) may be formed in the first source/drain recess 94A in the first region 95 of the semiconductor device 120 to mask the first source/drain recess 94A while lower epitaxial source/drain regions 108L are formed in the second source/drain recess 94B in the second region 97 and the third source/drain recess 94C in the third region 99. In an embodiment, the second region 97 is disposed between the first region 95 and the third region 99. The lower epitaxial source/drain regions 108L are for lower nanostructure-FETs of the CFETs, such as, for example the PMOS (P-channel Metal-Oxide-Semiconductor) portions of the CFETs of the SRAM cell. In an embodiment, the PMOS portions of the CFETs may be disposed in a region of the SRAM cell that may be referred to subsequently as the PMOS portion of the SRAM cell (e.g., a portion of the semiconductor device 120 that is disposed below the isolation structures 100).

The lower epitaxial source/drain regions 108L are in contact with the lower semiconductor nanostructures 66L and are not in contact with the upper semiconductor nanostructures 66U. In some embodiments, the lower epitaxial source/drain regions 108L exert stress in the respective channel regions of the lower semiconductor nanostructures 66L, thereby improving performance. The lower epitaxial source/drain regions 108L are formed in the second source/drain recess 94B and the third source/drain recess 94C such that a stack of the lower semiconductor nanostructures 66L is disposed between the lower epitaxial source/drain regions 108L. In some embodiments, the inner spacers 98 are used to separate the lower epitaxial source/drain regions 108L from the first dummy nanostructures 64A, which will be replaced with gate structures in subsequent processes.

The lower epitaxial source/drain regions 108L are epitaxially grown in the lower portions of the second source/drain recess 94B and the third source/drain recess 94C. For example, the lower epitaxial source/drain regions 108L may be grown laterally from exposed sidewalls of the lower semiconductor nanostructures 66L, as well as from bottom surfaces of the fins 60/substrate 50 in the source/drain recesses 94. During the epitaxy of the lower epitaxial source/drain regions 108L, the middle semiconductor nanostructures 66M and/or the upper semiconductor nanostructures 66U in the second source/drain recess 94B and the third source/drain recess 94C may be masked to prevent undesired epitaxial growth on the middle semiconductor nanostructures 66M and/or the upper semiconductor nanostructures 66U. After the lower epitaxial source/drain regions 108L are grown, the masks on the middle semiconductor nanostructures 66M and/or the upper semiconductor nanostructures 66U may then be removed. In addition, the masking layer in the first source/drain recess 94A in the first region 95 of the semiconductor device 120 may be removed using a suitable etching process. The lower epitaxial source/drain regions 108L have a conductivity type that is suitable for the device type of the lower nanostructure-FETs. In some embodiments, the lower epitaxial source/drain regions 108L are p-type source/drain regions, such as for the PMOS portion of the CFETs, as an example. In some embodiments, the lower epitaxial source/drain regions 108L are n-type source/drain regions. For example, if the lower semiconductor nanostructures 66L are silicon, the lower epitaxial source/drain regions 108L may include materials exerting a tensile strain on the lower semiconductor nanostructures 66L, such as silicon, carbon-doped silicon, phosphorous-doped silicon, silicon phosphide, silicon arsenide, or the like. In some embodiments, the lower epitaxial source/drain regions 108L are p-type source/drain regions. For example, if the lower semiconductor nanostructures 66L are silicon-germanium, the lower epitaxial source/drain regions 108L may include materials exerting a compressive strain on the lower semiconductor nanostructures 66L, such as silicon-germanium, boron-doped silicon-germanium, boron-doped silicon, germanium, germanium tin, or the like. The lower epitaxial source/drain regions 108L may have surfaces raised from respective upper surfaces of the lower semiconductor nanostructures 66L and may have facets.

In an embodiment, the lower epitaxial source/drain regions 108L are in situ doped during growth. Optionally, in other embodiments, the lower epitaxial source/drain regions 108L may be implanted with dopants to form source/drain regions, similar to the process previously discussed for forming lightly-doped source/drain regions, followed by an anneal. The source/drain regions may have an impurity concentration in the range of 10¹⁹ atoms/cm³ and 10²¹ atoms/cm³. The n-type and/or p-type impurities for source/drain regions may be any of the impurities previously discussed.

As a result of the epitaxy processes used to form the lower epitaxial source/drain regions 108L, upper surfaces of the lower epitaxial source/drain regions 108L have facets which expand laterally outward beyond sidewalls of the nanostructures 64, 66. In some embodiments, adjacent lower epitaxial source/drain regions 108L remain separated after the epitaxy process is completed. In other embodiments, these facets cause adjacent lower epitaxial source/drain regions 108L of a same nanostructure-FET to merge.

After the formation of the lower epitaxial source/drain regions 108L, a first contact etch stop layer (CESL) 112 and/or a first inter-layer dielectric (ILD) 114 may also be formed in the source/drain recesses 94, such as over the fin 62 in the first source/drain recess 94A, over the lower epitaxial source/drain region 108L in the second source/drain recess 94B, and over the lower epitaxial source/drain region 108L in the third source/drain recess 94C. The first ILD 114 may be disposed between subsequently formed upper epitaxial source/drain regions 108U and the lower epitaxial source/drain regions 108L in the second source/drain recess 94B and the third source/drain recess 94C, and between a subsequently formed upper epitaxial source/drain regions 108U and the fin 62 in the first source/drain recess 94A.

The first ILD 114 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The first CESL 112 may be formed between the first ILD 114 and the lower epitaxial source/drain regions 108L in the second source/drain recess 94B and the third source/drain recess 94C, and between the first ILD 114 and the fin 62 in the first source/drain recess 94A. The first CESL 112 may be formed of a dielectric material having a high etching selectivity to the dielectric material of the first ILD 114, such as silicon nitride, silicon oxide, silicon oxynitride, or the like, which may be formed by any suitable deposition process, such as CVD, ALD, or the like.

The first CESL 112 and/or the first ILD 114 may be formed by depositing a material for the first CESL 112 and depositing a material for the first ILD 114, followed by an etch-back process. In some embodiments, the first ILD 114 is initially etched, leaving the first CESL 112 unetched. An anisotropic etching process is then performed to remove the portions of the first CESL 112 that are higher than the first ILD 114. After the recessing, the sidewalls of the upper semiconductor nanostructures 66U in the first source/drain recess 94A, the second source/drain recess 94B, and the third source/drain recess 94C are exposed.

After the first CESL 112 and/or the first ILD 114 are formed in the source/drain recesses 94, the upper epitaxial source/drain regions 108U are formed in the source/drain recesses 94. The upper epitaxial source/drain regions 108U are for upper nanostructure-FETs of the CFETs, such as, for example the NMOS (N-channel Metal-Oxide-Semiconductor) portion of the CFETs of the SRAM cell. The first ILD 114 thus acts as isolation regions to prevent shorting of the lower and upper nanostructure-FETs. In an embodiment, the NMOS portions of the CFETs may be disposed in a region of the SRAM cell that may be referred to subsequently as the NMOS portion of the SRAM cell (e.g., a portion of the semiconductor device 120 that is disposed above the isolation structures 100).

The upper epitaxial source/drain regions 108U are in contact with the upper semiconductor nanostructures 66U and are not in contact with the lower semiconductor nanostructures 66L. In some embodiments, the upper epitaxial source/drain regions 108U exert stress in the respective channel regions of the upper semiconductor nanostructures 66U, thereby improving performance. The upper epitaxial source/drain regions 108U are formed in the source/drain recesses 94 such that each stack of the upper semiconductor nanostructures 66U is disposed between respective neighboring pairs of the upper epitaxial source/drain regions 108U. In some embodiments, the inner spacers 98 are used to separate the upper epitaxial source/drain regions 108U from the first dummy nanostructures 64A, which will be replaced with gate structures in subsequent processes.

The upper epitaxial source/drain regions 108U are epitaxially grown in the upper portions of the source/drain recesses 94 (e.g., the first source/drain recess 94A, the second source/drain recess 94B, and the third source/drain recess 94C). For example, the upper epitaxial source/drain regions 108U may be grown laterally from exposed sidewalls of the upper semiconductor nanostructures 66U. The upper epitaxial source/drain regions 108U have a conductivity type that is suitable for the device type of the upper nanostructure-FETs. The conductivity type of the upper epitaxial source/drain regions 108U may be opposite the conductivity type of the lower epitaxial source/drain regions 108L. Put another way, the upper epitaxial source/drain regions 108U may be oppositely doped from the lower epitaxial source/drain regions 108L. In some embodiments, the upper epitaxial source/drain regions 108U are n-type source/drain regions, such as for the NMOS portion of the CFETs, as an example. For example, if the upper semiconductor nanostructures 66U are silicon, the upper epitaxial source/drain regions 108U may include materials exerting a tensile strain on the upper semiconductor nanostructures 66U, such as silicon, carbon-doped silicon, phosphorous-doped silicon, silicon phosphide, silicon arsenide, or the like. In some embodiments, the upper epitaxial source/drain regions 108U are p-type source/drain regions. For example, if the upper semiconductor nanostructures 66U are silicon-germanium, the upper epitaxial source/drain regions 108U may include materials exerting a compressive strain on the upper semiconductor nanostructures 66U, such as silicon-germanium, boron-doped silicon-germanium, boron-doped silicon, germanium, germanium tin, or the like. The upper epitaxial source/drain regions 108U may have surfaces raised from respective upper surfaces of the upper semiconductor nanostructures 66U and may have facets.

The upper epitaxial source/drain regions 108U may be implanted with dopants to form source/drain regions, similar to the process previously discussed for forming lightly-doped source/drain regions, followed by an anneal. The source/drain regions may have an impurity concentration in the range of 10¹⁹ atoms/cm³ and 10²¹ atoms/cm³. The n-type and/or p-type impurities for source/drain regions may be any of the impurities previously discussed. In some embodiments, the upper epitaxial source/drain regions 108U are in situ doped during growth.

As a result of the epitaxy processes used to form the upper epitaxial source/drain regions 108U, upper surfaces of the upper epitaxial source/drain regions 108U have facets which expand laterally outward beyond sidewalls of the nanostructures 64, 66. In some embodiments, adjacent upper epitaxial source/drain regions 108U remain separated after the epitaxy process is completed. In other embodiments, these facets cause adjacent upper epitaxial source/drain regions 108U of a same nanostructure-FET to merge.

After the formation of the upper epitaxial source/drain regions 108U, a second CESL 122 and/or a second ILD 124 may be formed on the upper epitaxial source/drain regions 108U. The second ILD 124 is deposited over the upper epitaxial source/drain regions 108U. The second ILD 124 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The second CESL 122 may be formed between the second ILD 124 and the upper epitaxial source/drain regions 108U. The second CESL 122 may be formed of a dielectric material having a high etching selectivity to the dielectric material of the second ILD 124, such as, silicon nitride, silicon oxide, silicon oxynitride, or the like, which may be formed by any suitable deposition process, such as CVD, ALD, or the like.

The second CESL 122 and/or the second ILD 124 may be formed by depositing a material for the second CESL 122 and depositing a material for the second ILD 124. A removal process is then performed to level the top surfaces of the second ILD 124 with the top surfaces of the gate spacers 90 and the masks 86 (if present) or the dummy gates 84. In some embodiments, a planarization process such as a chemical mechanical polish (CMP), an etch-back process, combinations thereof, or the like may be utilized. The planarization process may also remove the masks 86 on the dummy gates 84, and portions of the gate spacers 90 along sidewalls of the masks 86. After the planarization process, top surfaces of the second ILD 124, the gate spacers 90, and the masks 86 (if present) or the dummy gates 84 are substantially coplanar (within process variations). Accordingly, the top surfaces of the masks 86 (if present) or the dummy gates 84 are exposed through the second ILD 124. In the illustrated embodiment, the masks 86 remain after the removal process. In other embodiments, the masks 86 are removed such that the top surfaces of the dummy gates 84 are exposed through the second ILD 124.

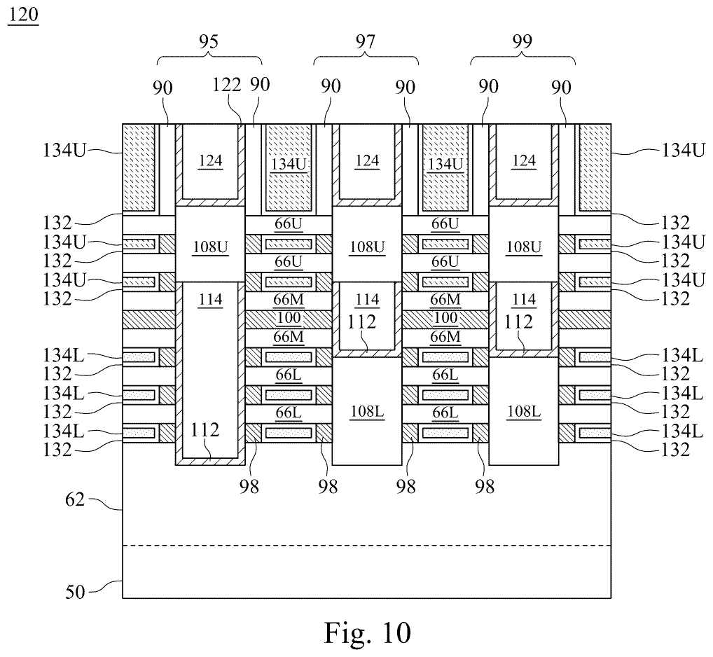

In FIG. 10, the dummy gates 84 are removed in one or more etching steps, so that recesses are formed between the gate spacers 90. Portions of the dummy dielectrics 82 in the recesses are also removed. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the second ILD 124, the isolation structures 100, the inner spacers 98, and the gate spacers 90. Each recess between the gate spacers 90 exposes and/or overlies portions of nanostructures 64, 66 which act as the channel regions in the resulting devices. The portions of the nanostructures 64, 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A are then removed to form openings in regions between the semiconductor nanostructures 66. The remaining portions of the first dummy nanostructures 64A can be removed by any acceptable etch process that selectively etches the material of the first dummy nanostructures 64A at a faster rate than the materials of the semiconductor nanostructures 66, the inner spacers 98, and the isolation structures 100. The etching may be isotropic. For example, when the first dummy nanostructures 64A are formed of silicon-germanium, the semiconductor nanostructures 66 are formed of silicon, the inner spacers 98 are formed of silicon oxycarbonitride, and the isolation structures 100 are formed of silicon oxycarbonitride, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the semiconductor nanostructures 66 and expand the openings between the semiconductor nanostructures 66.

Next, gate dielectrics 132 and gate electrodes 134 (including lower gate electrodes 134L and upper gate electrodes 134U) are formed for replacement gates. Each respective pair of a gate dielectric 132 and a gate electrode 134 (including an upper gate electrode 134U and/or a lower gate electrode 134L) may be collectively referred to as a “gate structure.” Each respective pair of a gate dielectric 132 and a gate electrode 134 (including an upper gate electrode 134U and/or a lower gate electrode 134L) may also be collectively referred to as a “gate stack.” Each gate structure extends along at least three sides (e.g., a top surface, a sidewall, and a bottom surface) of a channel region of a semiconductor nanostructure 66. The gate structures may also extend along sidewalls and/or a top surface of a semiconductor fin 62.

The gate dielectrics 132 include one or more gate dielectric layer(s) disposed around the lower semiconductor nanostructures 66L, the upper semiconductor nanostructures 66U, and the isolation structures 96. Specifically, the gate dielectrics 132 are disposed on the top surfaces of the fins 62; on the top surfaces, the sidewalls, and the bottom surfaces of the semiconductor nanostructures 66; and on the sidewalls of the gate spacers 90. The gate dielectrics 132 wrap around all (e.g., four) sides of the semiconductor nanostructures 66. The gate dielectrics 132 may be formed of an oxide such as silicon oxide or a metal oxide, a silicate such as a metal silicate, combinations thereof, multi-layers thereof, or the like. Additionally or alternatively, the gate dielectrics 132 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the gate dielectrics 132 may be formed by molecular-beam deposition (MBD), ALD, PECVD, or the like. Although single-layered gate dielectrics 132 are illustrated, the gate dielectrics 132 may include any number of interfacial layers and any number of main layers. For example, the gate dielectrics 132 may include an interfacial layer and an overlying high-k dielectric layer.

The lower gate electrodes 134L include one or more gate electrode layer(s) disposed over the gate dielectrics 132 and around the lower semiconductor nanostructures 66L. The lower gate electrodes 134L are disposed in the lower portions of the recesses between the gate spacers 90 and in the openings between the lower semiconductor nanostructures 66L. The lower gate electrodes 134L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 134L may include any number of work function tuning layers, any number of barrier layers, any number of glue layers, and a fill material.

The lower gate electrodes 134L are formed of material(s) that are suitable for the device type of the lower nanostructure-FETs. For example, the lower gate electrodes 134L may include one or more work function tuning layer(s) formed of work function tuning metal(s) that are suitable for the device type of the lower nanostructure-FETs. In some embodiments, the lower gate electrodes 134L include an n-type work function tuning layer, which may be formed of an n-type work function tuning metal such as titanium aluminum, titanium aluminum carbide, tantalum aluminum, tantalum carbide, combinations thereof, or the like. In some embodiments, the lower gate electrodes 134L include a p-type work function tuning layer, which may be formed of a p-type work function tuning metal such as titanium nitride, tantalum nitride, combinations thereof, or the like. Additionally or alternatively, the lower gate electrodes 134L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The upper gate electrodes 134U include one or more gate electrode layer(s) disposed over the gate dielectrics 132 and around the upper semiconductor nanostructures 66U. The upper gate electrodes 134U are disposed in the upper portions of the recesses between the gate spacers 90 and in the openings between the upper semiconductor nanostructures 66U. The upper gate electrodes 134U may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the upper gate electrodes 134U may include any number of work function tuning layers, any number of barrier layers, any number of glue layers, and a fill material.

The upper gate electrodes 134U are formed of material(s) that are suitable for the device type of the upper nanostructure-FETs. For example, the upper gate electrodes 134U may include one or more work function tuning layer(s) formed of work function tuning metal(s) that are suitable for the device type of the upper nanostructure-FETs. In some embodiments, the upper gate electrodes 134U include an n-type work function tuning layer, which may be formed of an n-type work function tuning metal such as titanium aluminum, titanium aluminum carbide, tantalum aluminum, tantalum carbide, combinations thereof, or the like. In some embodiments, the upper gate electrodes 134U include a p-type work function tuning layer, which may be formed of a p-type work function tuning metal such as titanium nitride, tantalum nitride, combinations thereof, or the like. The work function tuning metal(s) of the upper gate electrodes 134U may be different to or the same as the work function tuning metal(s) of the lower gate electrodes 134L. Additionally or alternatively, the upper gate electrodes 134U may include a dipole-inducing element that is suitable for the device type of the upper nanostructure-FETs. Acceptable dipole-inducing elements include lanthanum, aluminum, scandium, ruthenium, zirconium, erbium, magnesium, strontium, and combinations thereof. The dipole-inducing elements the upper gate electrodes 134U may be different than the dipole-inducing elements of the lower gate electrodes 134L.

In some embodiments, isolation layers (not separately illustrated) are formed between the lower gate electrodes 134L and the upper gate electrodes 134U. The isolation layers act as isolation features between the lower gate electrodes 134L and the upper gate electrodes 134U. The isolation layers may be formed of a dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. In embodiments where the isolation layers are formed, the isolation layers and the isolation structures 100 together isolate the upper gate electrodes 134U from the lower gate electrodes 134L. Accordingly, an upper nanostructure-FET may be isolated from a lower nanostructure-FET by a combination of an isolation structure 100 and an isolation layer. In some embodiments where the isolation layers are omitted, an upper nanostructure-FET may be coupled to a lower nanostructure-FET. When the isolation layers are omitted, the lower gate electrodes 134L may be physically and electrically coupled to the upper gate electrodes 134U.

As an example to form the gate structures, one or more gate dielectric layer(s) may be deposited in the recesses between the gate spacers 90 and the openings between the semiconductor nanostructures 66. The gate dielectric layer(s) may also be deposited on the top surfaces of the second ILD 124 and the gate spacers 90. Subsequently, one or more lower gate electrode layer(s) may be deposited on the gate dielectric layer(s), and in the remaining portions of the recesses between the gate spacers 90 and the openings between the semiconductor nanostructures 66. The lower gate electrode layer(s) may then be recessed. Any acceptable etch process, such as a dry etch, a wet etch, the like, or a combination thereof, may be performed to recess the lower gate electrode layer(s). The etching may be isotropic, such as an etch-back process that removes the lower gate electrode layer(s) from the upper portions of the recesses between the gate spacers 90, such that the lower gate electrode layer(s) remain in the openings between the lower semiconductor nanostructures 66L. In embodiments where the isolation layers are formed, an isolation material is conformally formed on the lower gate electrode layer(s) and then recessed. Any acceptable etch process, such as a dry etch, a wet etch, the like, or a combination thereof, may be performed to recess the isolation material. Subsequently, one or more upper gate electrode layer(s) may be deposited on the isolation material (if present) or the lower gate electrode layer(s), and in the remaining portions of the recesses between the gate spacers 90 and the openings between the upper semiconductor nanostructures 66U. A removal process is performed to remove the excess portions of the upper gate electrode layer(s), which excess portions are over the top surfaces of the gate spacers 90 and the second ILD 124, such that the upper gate electrode layer(s) remain in the openings between the upper semiconductor nanostructures 66U. In some embodiments, a planarization process such as a chemical mechanical polish (CMP), an etch-back process, combinations thereof, or the like may be utilized. The gate dielectric layer(s), after the removal process, have portions remaining in the recesses between the gate spacers 90 and the openings between the semiconductor nanostructures 66 (thus forming the gate dielectrics 132). The lower gate electrode layer(s), after the removal process, have portions left in the lower portions of the recesses between the gate spacers 90 and in the openings between the lower semiconductor nanostructures 66L (thus forming the lower gate electrodes 134L). The upper gate electrode layer(s), after the removal process, have portions left in the upper portions of the recesses between the gate spacers 90 and in the openings between the upper semiconductor nanostructures 66U (thus forming the upper gate electrodes 134U). When a planarization process is utilized, the top surfaces of the gate spacers 90, the second ILD 124, the gate dielectrics 132, and the upper gate electrodes 134U are coplanar (within process variations).

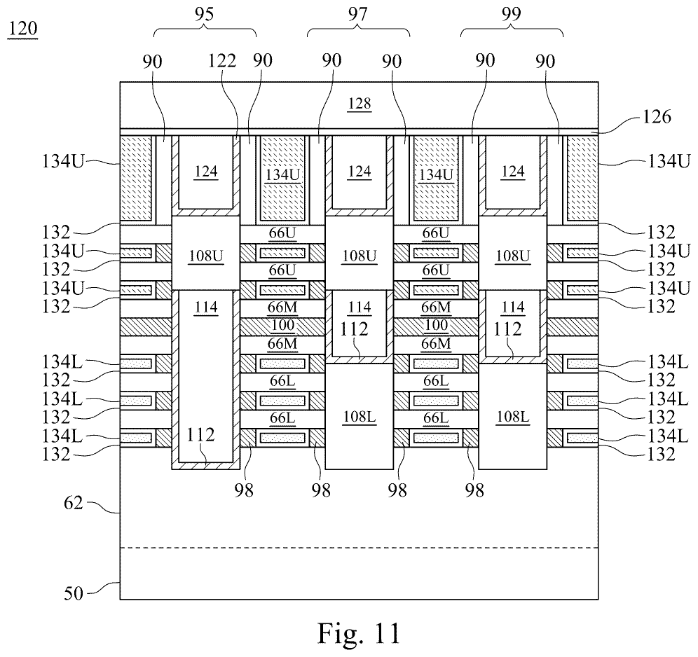

In FIG. 11, a third ILD 128 is deposited over the gate spacers 90, the second CESL 122, the second ILD 124, and the upper gate electrodes 134U. In some embodiments, the third ILD 128 is a flowable film formed by a flowable CVD method, which is subsequently cured. In some embodiments, the third ILD 128 is formed of a dielectric material such as PSG, BSG, BPSG, USG, or the like, which may be deposited by any suitable method, such as CVD, PECVD, or the like.

In some embodiments, an etch stop layer (ESL) 126 is formed between the third ILD 128 and the gate spacers 90, the second CESL 122, the second ILD 124, and the upper gate electrodes 134U. The ESL 126 may include a dielectric material having a high etching selectivity to the dielectric material of the third ILD 128, such as, silicon nitride, silicon oxide, silicon oxynitride, or the like.

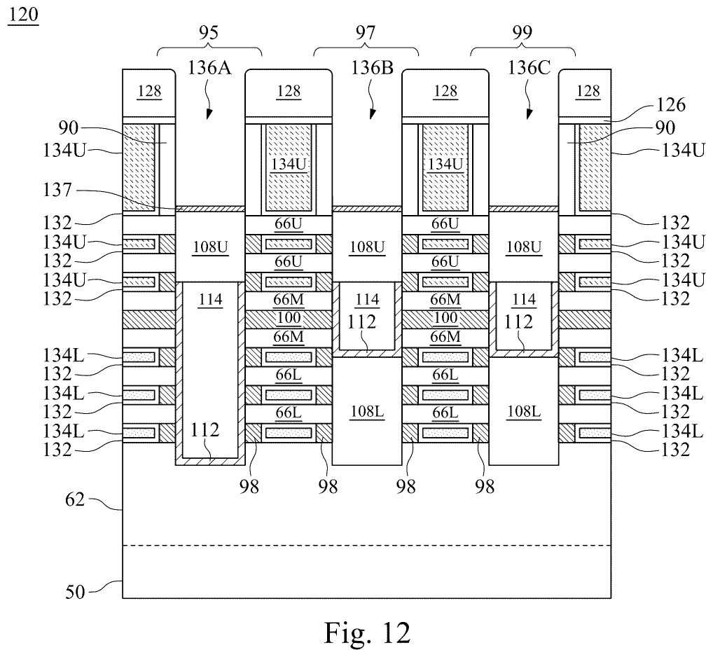

In FIG. 12, openings 136 are formed that extend through the third ILD 128, the ESL 126, the second ILD 124 and the second CESL 122 to expose top surfaces of the upper epitaxial source/drain regions 108U. For example, the openings 136 comprise an opening 136A in the first region 95, an opening 136B in the second region 97, and an opening 136C in the third region 99. The openings 136 may be formed using acceptable photolithography and etching techniques. In some embodiments, a protection layer 137 is formed in the openings 136, such as on top surfaces of the third ILD 128 and the upper epitaxial source/drain regions 108U, and on sidewalls of the third ILD 128, the ESL 126, and the gate spacers 90. The protection layer 137 may be conformally formed using a deposition process, such as, for example, CVD, ALD, or the like. The protection layer 137 may include a dielectric material having a high etching selectivity to a material of a subsequently formed sacrificial layer 138 (described below). For example, the protection layer 137 may comprise, for example, silicon nitride, silicon oxynitride, or the like. The protection layer 137 may then be patterned using suitable photolithography and etching techniques to remove portions of the protection layer 137 on the top surfaces of the third ILD 128 and on sidewalls of the third ILD 128, the ESL 126, and portions of the gate spacers 90. Remaining portions of the protection layer 137 are disposed on the top surfaces of the upper epitaxial source/drain regions 108U.

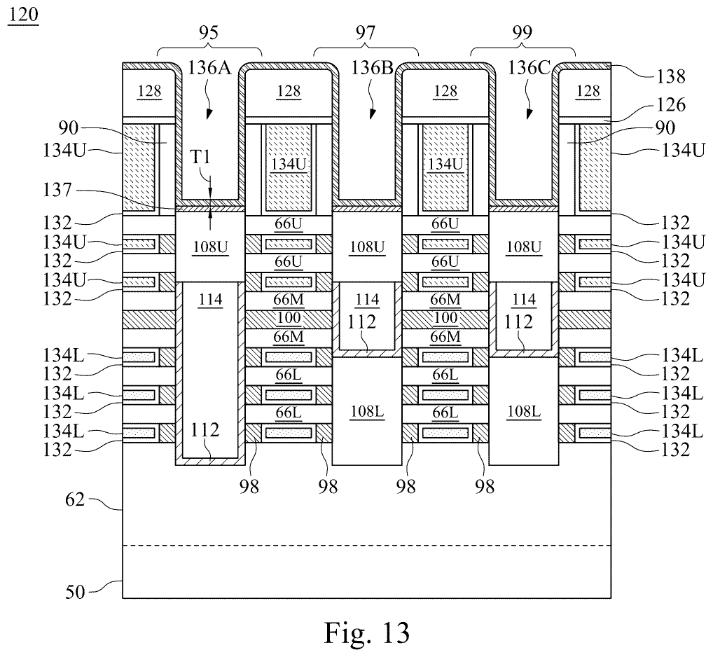

In FIG. 13, a sacrificial layer 138 is formed in the openings 136, such as on top surfaces of the third ILD 128 and the protection layer 137, and on sidewalls of the third ILD 128, the ESL 126, and the gate spacers 90. The sacrificial layer 138 may be conformally formed using a deposition process, such as, for example, CVD, ALD, or the like. The sacrificial layer 138 may comprise, for example, undoped silicon, silicon oxide, or the like. The sacrificial layer 138 may have a thickness T1 that is in a range from 2 nm to 3 nm.

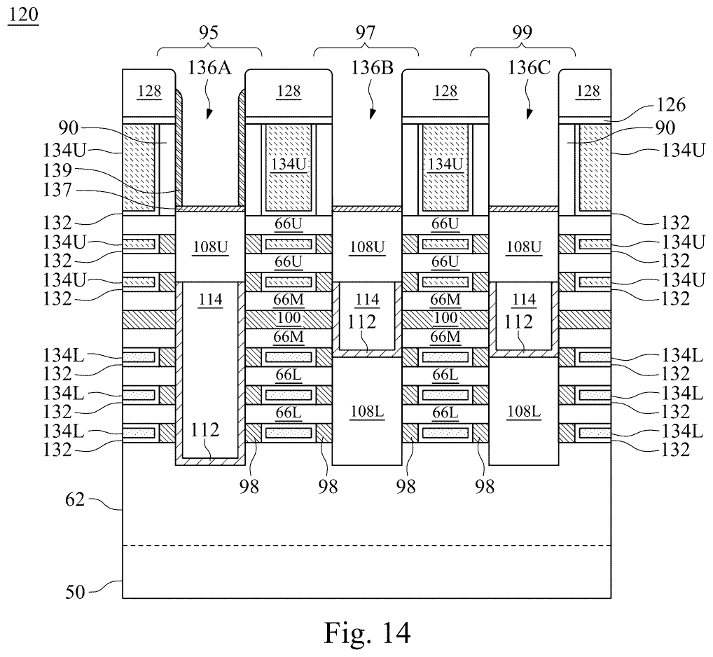

In FIG. 14, the sacrificial layer 138 is patterned to remove portions of the sacrificial layer 138 on the top surfaces of third ILD 128, as well as portions of the sacrificial layer 138 in the openings 136B and 136C in the second region 97 and the third region 99, respectively. In addition, portions of the sacrificial layer 138 on a bottom surface of the opening 136A, and on upper sidewalls of the opening 136A in the first region 95 are removed. Remaining portions of the sacrificial layer 138 form the sacrificial spacers 139 that are disposed on sidewalls of the opening 136A, such as on sidewalls of the third ILD 128, the ESL 126, and the gate spacers 90 in the opening 136A.

To pattern the sacrificial layer 138, a suitable masking layer (e.g., a photoresist, a Bottom Anti-Reflective Coating (BARC) layer, or the like) may be formed to partially fill in the opening 136A in the first region 95 of the semiconductor device 120 to mask the opening 136A while a first etching process is performed to remove the portions of the sacrificial layer 138 in the openings 136B and 136C in the second region 97 and the third region 99, respectively. In addition, during the first etching process, the portions of the sacrificial layer 138 on the upper sidewalls of the opening 136A (e.g., that are disposed above the masking layer in the opening 136A) are removed, as well as the portions of the sacrificial layer 138 on the top surfaces of third ILD 128. The first etching process may be, for example, a dry etch process that is performed using chlorine, or the like, as etchants.

After the first etching process is performed, the masking layer in the opening 136A in the first region 95 may be removed using a suitable etching process. A second etching process may then be performed to remove a horizontal portion of the sacrificial layer 138 on the bottom surface of the opening 136A to expose a top surface of the protection layer 137 in the opening 136A. The second etching process may be, for example, a dry etch process that is performed using chlorine, or the like, as etchants. After the first etching process and the second etching process are performed, the remaining portions of the sacrificial layer 138 on the sidewalls of the opening 136A form the sacrificial spacers 139.

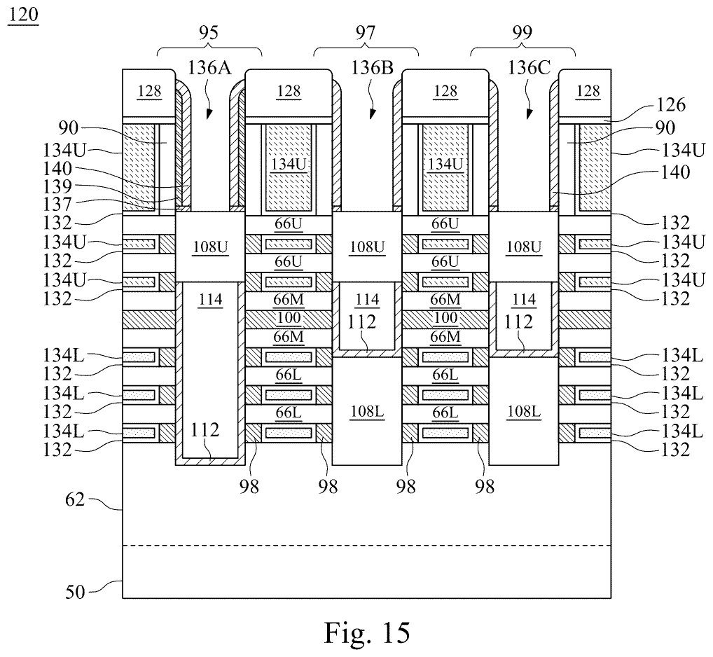

In FIG. 15, spacers 140 are formed on the sacrificial spacers 139 in the opening 136A in the first region 95. The spacers 140 are also formed on sidewalls in the openings 136B and the 136C in the second region 97 and the third region 99, respectively, such as on sidewalls of the third ILD 128, the ESL 126, and the gate spacers 90. The spacers 140 may be formed by forming a spacer layer using a suitable deposition process, such as CVD, ALD, or the like, and then patterning the spacer layer by a suitable etching process, such as an isotropic etching process (e.g., a wet etching process), an anisotropic etching process (e.g., a dry etching process), or the like. The spacer layer may comprise a dielectric material, such as for example, silicon nitride, or the like. The spacer layer may be formed on top surfaces of the third ILD 128 and the protection layer 137, as well as on sidewalls of the third ILD 128, the ESL 126, and the gate spacers 90. After the etching process, the spacers 140 may remain on the sacrificial spacers 139 in the opening 136A in the first region 95, as well as on the sidewalls in the openings 136B and the 136C in the second region 97 and the third region 99, respectively. After the formation of the spacers 140, the openings 136 may be extended through the protection layer 137 to expose top surfaces of the upper epitaxial source/drain regions 108U. The openings 136 may be extended through the protection layer 137 using for example, acceptable photolithography and etching techniques. In an embodiment, after extending the opening 136A through the protection layer 137, portions of the protection layer 137 remain disposed under the spacers 140 and the sacrificial spacers 139 in the opening 136A.

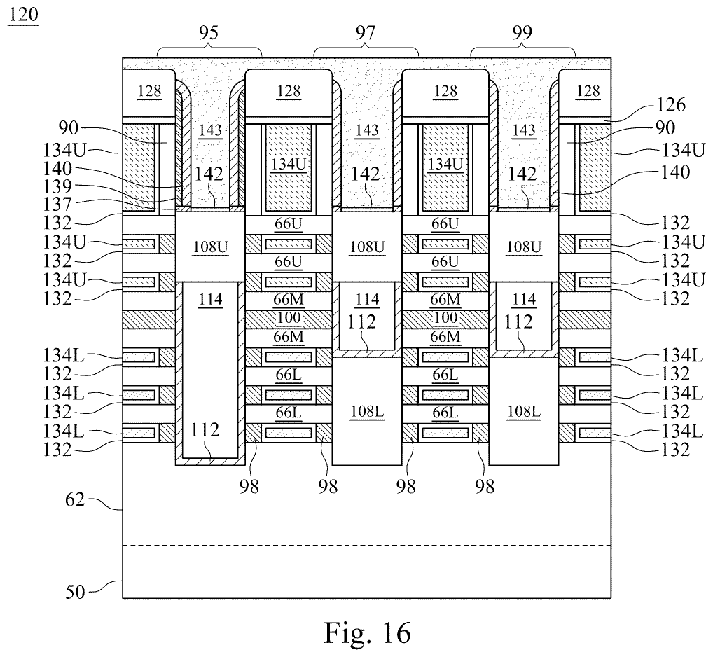

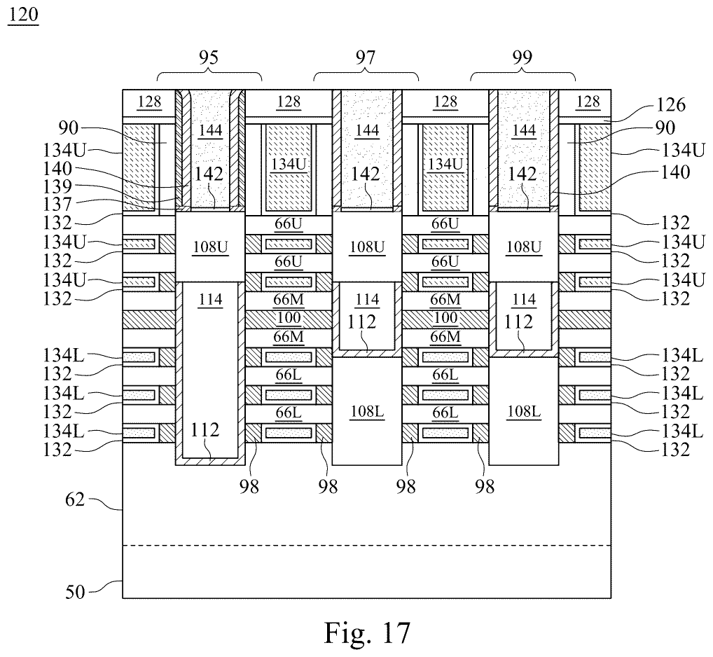

In FIGS. 16-17, metal contacts 144 are formed in the openings 136. For example, the metal contacts 144 may be formed to extend through the third ILD 128, the ESL 126, and between adjacent upper gate electrodes 134U to electrically couple to the upper epitaxial source/drain regions 108U. In FIG. 16, a liner (not separately illustrated), such as a diffusion barrier layer, an adhesion layer, or the like, and a conductive material 143 are formed in the openings 136 (e.g., the opening 136A, the opening 136B, and the opening 136C). The liner may include titanium, titanium nitride, tantalum, tantalum nitride, or the like. The conductive material 143 may be cobalt, tungsten, copper, a copper alloy, silver, gold, aluminum, nickel, or the like.

In FIG. 17, a planarization process such as a chemical mechanical polish (CMP) is performed to remove excess material of the liner and the conductive material 143 from a top surface of the third ILD 128. In an embodiment, the planarization process may also remove portions of the spacers 140, the sacrificial spacers 139, and the third ILD 128 such that after the planarization process, top surfaces of the spacers 140, the sacrificial spacers 139, the third ILD 128, the liner, and the metal contacts 144 are substantially coplanar (within process variations).

Optionally, metal-semiconductor alloy regions 142 are formed at the interfaces between the upper epitaxial source/drain regions 108U and the metal contacts 144. The metal-semiconductor alloy regions 142 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 142 can be formed before the material(s) of the metal contacts 144 by depositing a metal in the openings 136 and then performing a thermal anneal process. The metal can be any metal capable of reacting with the semiconductor materials (e.g., silicon, silicon-germanium, germanium, etc.) of the upper epitaxial source/drain regions 108U to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings 136, such as from surfaces of the metal-semiconductor alloy regions 142. The material(s) of the metal contacts 144 can then be formed on the metal-semiconductor alloy regions 142.

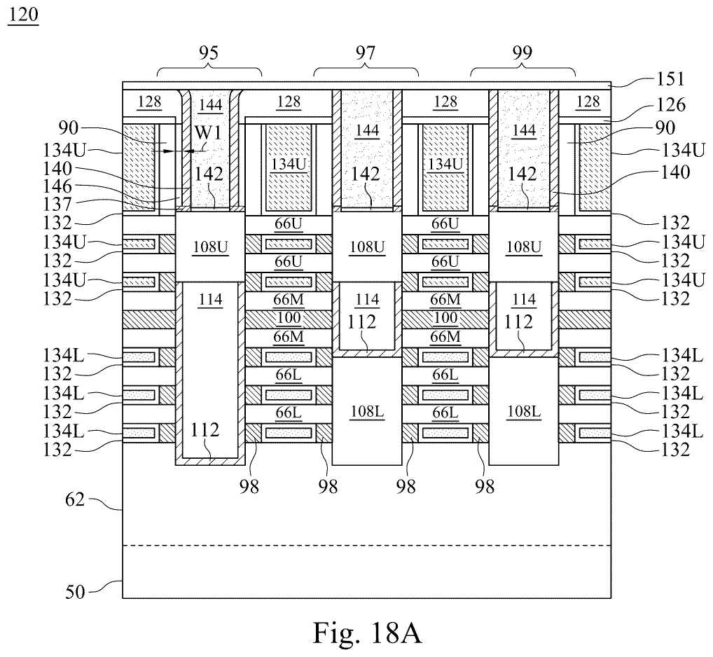

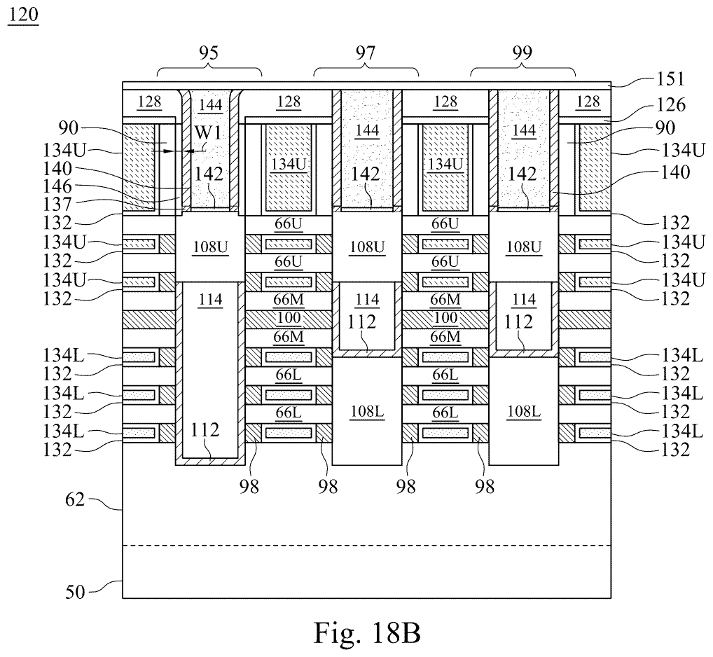

In FIG. 18A, the sacrificial spacers 139 in the first region 95 are removed to form recesses between the gate spacers 90 and the spacers 140. The recesses are adjacent the spacers 140, and are over the protection layer 137 and the upper epitaxial source/drain region 108U in the first region 95. The recesses may also be between the spacers 140 and the third ILD 128 in the first region 95, and between the spacers 140 and the ESL 126 in the first region 95. In an embodiment, the recesses surround the spacers 140 and the metal contact 144 in the first region 95. The sacrificial spacers 139 may be removed by performing any acceptable etch process, such as one that is selective to the material of the sacrificial spacers 139 (e.g., selectively etches the material of the sacrificial spacers 139 at a faster rate than the materials of the spacers 140 and the third ILD 128. In an embodiment, performing the etch process may comprise performing a dry or wet etch process using chlorine, hydrogen fluoride, or the like, as an etchant. The width W1 of each of the recesses may be substantially the same as the thickness T1 of the sacrificial spacers 139. For example, the width W1 may be in a range from 2 nm to 3 nm. In this embodiment, an entirety of the sacrificial spacers 139 is removed such that no residual portions of the sacrificial spacers 139 remain on the protection layer 137 in the first region 95 after the etch process is performed. Accordingly, the protection layer 137 in the first region 95 is exposed to the recesses. In another embodiment, only portions of the sacrificial spacers 139 are removed, such that some residual portions of the sacrificial spacers 139 remain on the protection layer 137 in the first region 95 after the etch process is performed. It should be noted that no recesses are formed in the second region 97 and the third region 99. In other embodiments, the etch process to remove the sacrificial spacers 139 may also partially etch portions of the protection layer 137 and the upper epitaxial source/drain region 108U below the sacrificial spacers 139. As a result, the recesses may extend through the protection layer 137 and partially through the upper epitaxial source/drain region 108U to form “teeth-like” features at edges of the upper epitaxial source/drain region 108U as shown in FIG. 18B.

After the sacrificial spacers 139 are removed, in some embodiments, an etch stop layer (ESL) 151 is formed over the third ILD 128, the spacers 140, and the metal contacts 144. The ESL 151 may include a dielectric material having a high etching selectivity to the dielectric material of the third ILD 128, such as, silicon nitride, silicon oxide, silicon oxynitride, or the like.

After the formation of the ESL 151, an implantation process may be performed to introduce dopants into portions of the third ILD 128. The implantation process may be used to direct an implantation species (or dopants) such as for example, germanium, or the like, into the portions of the third ILD 128 below the ESL 151 to facilitate an expansion of a material of the third ILD 128. The expansion of the material of the third ILD 128 may result in the third ILD 128 sealing top portions of the recesses between the spacers 140 and the third ILD 128 in the first region 95, and between the spacers 140 and the ESL 126 in the first region 95. In this way, after the implantation process is performed, an air-gap 146 is formed that surrounds portions of the spacers 140 and the metal contact 144 in the first region 95. In an embodiment, top surfaces of the protection layer 137 or the upper epitaxial source/drain region 108U in the first region 95 are exposed to the air-gap 146.

In FIGS. 19A-19B, a dielectric layer 150 is deposited over the ESl 151. The dielectric layer 150 may be formed of any suitable dielectric material, such as silicon nitride, silicon oxide, or the like, which may be formed by a deposition process, such as CVD, ALD, or the like. Contact via 152 is then formed to extend through the dielectric layer 150 and the ESL 151 to electrically couple to the metal contact 144 in the first region 95. As an example to form the contact via 152, an opening for the contact via 152 is formed through the dielectric layer 150 and the ESL 151. The opening may be formed using acceptable photolithography and etching techniques. A liner (not separately illustrated), such as a diffusion barrier layer, an adhesion layer, or the like, and a conductive material are formed in the opening. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the dielectric layer 150. The remaining liner and conductive material form the contact via 152 in the opening. The contact via 152 may be used to electrically connect the metal contact 144 in the first region 95 to a subsequently formed bit line 149.

Referring further to FIGS. 19A-19B, a dielectric layer 148 may be deposited over the dielectric layer 150 and the contact via 152. The dielectric layer 148 may be formed of any suitable dielectric material, such as silicon nitride, silicon oxide, or the like, which may be formed by a deposition process, such as CVD, ALD, or the like. After the formation of the dielectric layer 148, a bit line 149 may be formed in the dielectric layer 148. The bit line 149 may comprise a conductive strip, and may be electrically connected to the metal contact 144 in the first region 95 through the contact via 152. To form the bit line 149, a trench may be formed in the dielectric layer 148. The trench may be formed using acceptable photolithography and etching techniques. The trench may then be filled with a conductive material using CVD, physical vapor deposition (PVD), electro-chemical plating (ECP), electroless plating, or the like. The conductive material may comprise a material such as Cu, Al, Ti, Ta, W, Pt, Ni, Cr, Ru, TiN, TaN, combinations thereof, multilayers thereof, or the like. Any excess conductive material may be removed by, for example, a planarization process such as a chemical mechanical polish (CMP) process. The bit line 149 may extend along a lengthwise direction, which is perpendicular to the lengthwise direction of the gate electrodes 134. In an embodiment, a sub-region of the first region 95 that is disposed within the NMOS portion of the SRAM cell may also be referred to subsequently as a bit line region of the semiconductor device 120. In an embodiment, a sub-region of the second region 97 that is disposed within the NMOS portion of the SRAM cell may also be referred to subsequently as a node region of the semiconductor device 120. In an embodiment, the metal contact 144 that is disposed in a sub-region of the third region 99 that is within the NMOS portion of the SRAM cell may be a voltage source supply (VSS) contact (e.g., which may be electrically connected to sources of NMOS portions of the CFETs).

Advantages can be achieved by removing the sacrificial spacers 139 in the first region 95 to form the recesses that are adjacent the spacers 140, the recesses being over the protection layer 137 and the upper epitaxial source/drain region 108U in the first region 95. The recesses may be formed to surround the spacers 140 and the metal contact 144 in the first region 95, wherein the metal contact 144 in the first region 95 is a bit line contact and is electrically connected to the subsequently formed bit line 149. After the sacrificial spacers 139 are removed, the etch stop layer (ESL) 151 is formed over the third ILD 128, the spacers 140, and the metal contacts 144. After the formation of the ESL 151, the implantation process is performed to introduce dopants (e.g., germanium, or the like) into portions of the third ILD 128 to facilitate an expansion of a material of the third ILD 128. The expansion of the material of the third ILD 128 may result in the third ILD 128 sealing top portions of the recesses between the spacers 140 and the third ILD 128 in the first region 95, and between the spacers 140 and the ESL 126 in the first region 95. In this way, after the implantation process is performed, the air-gap 146 is formed that surrounds portions of the spacers 140 and the metal contact 144 in the first region 95. The air-gap 146 may have the width W1 that is in a range from 2 nm to 3 nm. No air-gap is formed to surround portions of the spacers 140 and the metal contacts 144 in the second region 97 or the third region 99.

These advantages include the air-gap 146 having the width W1 that is in the range from 2 nm to 3 nm allowing for a reduction of the capacitance associated with the bit line contact (e.g., the metal contact 144 in the first region 95). As a result, the combined capacitance of the bit line 149 and the bit line contact (e.g., the metal contact 144 in the first region 95) can be reduced, and less charge may be required to change the voltage of the bit line 149 during read and write operations. This leads to quicker read and write operations in the SRAM cell. As a result, the speed of the SRAM cell operations can be increased. In addition, due to no air-gap being formed to surround the portions of the spacers 140 and the metal contacts 144 in each of the second region 97 and the third region 99, each of the metal contacts 144 in the second region 97 and the third region 99 can be formed having larger dimensions (e.g., larger widths) as there is no need to accommodate the space that would be occupied by the air-gap. The increased dimensions of the metal contacts 144 in each of the second region 97 and the third region 99 lead to lower electrical resistances through these metal contacts 144, and as a result, SRAM cell performance can be improved.

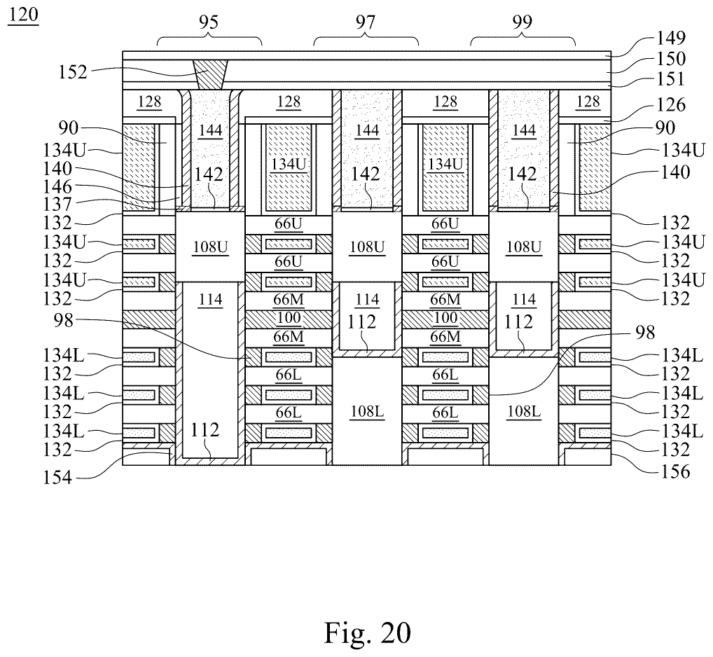

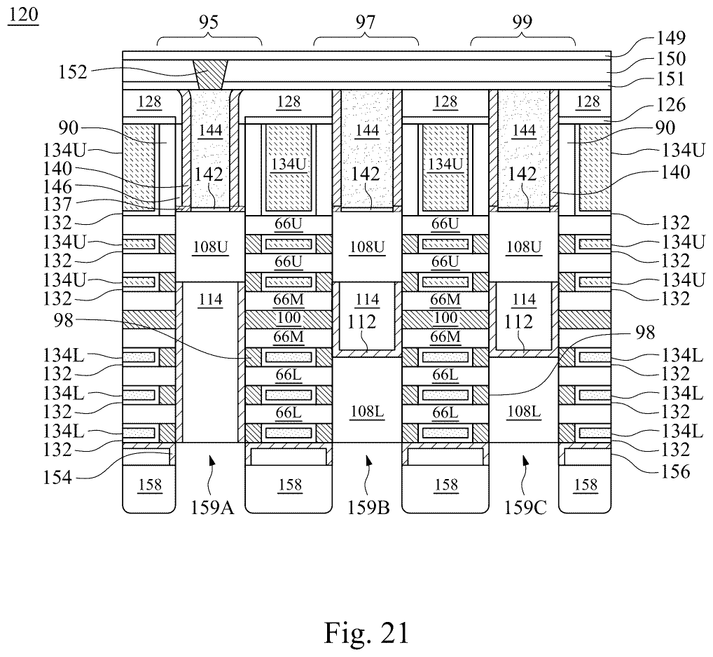

In FIG. 20, A planarization process may then be performed on the backside of the semiconductor device 120 (e.g., on the substrate 50). In some embodiments, the planarization process may include a combination of CMP and/or etch-back processes, for example. The planarization process and/or etching processes may remove the substrate 50 and the fins 62, exposing the isolation regions 70. Then, one or more etching processes are performed to remove the isolation regions 70. An ESL 154 can be deposited over the backside of the semiconductor device 120, such as over the gate dielectrics 132, the lower gate electrodes 134L, the first CESL 112, the first ILD 114, and the lower epitaxial source/drain regions 108L. The ESL 154 may include a dielectric material having a high etching selectivity to a dielectric material of a subsequently formed ILD 156, such as, silicon nitride, silicon oxide, silicon oxynitride, or the like. After the formation of the ESL 154, the ILD 156 is deposited over the backside of the semiconductor device 120, such as over the ESL 154. The ILD 156 is a flowable film formed by a flowable CVD method, which is subsequently cured. In some embodiments, the ILD 156 is formed of a dielectric material such as PSG, BSG, BPSG, USG, or the like, which may be deposited by any suitable method, such as CVD, PECVD, or the like. A removal process is then performed to level bottom surfaces of the ILD 156 and the ESL 154 with bottom surfaces of the first CESL 112 and the lower epitaxial source/drain regions 108L. In some embodiments, a planarization process such as a chemical mechanical polish (CMP), an etch-back process, combinations thereof, or the like may be utilized.

In FIG. 21, an ILD 158 may be deposited over the backside of the semiconductor device 120, such as over the ESL 154, the ILD 156, the first CESL 112, the first ILD 114, and the lower epitaxial source/drain regions 108L. The ILD 158 is a flowable film formed by a flowable CVD method, which is subsequently cured. In some embodiments, the ILD 158 is formed of a dielectric material such as PSG, BSG, BPSG, USG, or the like, which may be deposited by any suitable method, such as CVD, PECVD, or the like. After the formation of the ILD 158, openings 159 are formed that extend through the ILD 158, the ILD 156, and the ESL 154 to expose bottom surfaces of the lower epitaxial source/drain regions 108L and the first ILD 114. For example, the openings 159 comprise an opening 159A in the first region 95 that exposes bottom surfaces of the first CESL 112 and the first ILD 114, and openings 159B and 159C in the second region 97 and the third region 99 that expose bottom surfaces of the lower epitaxial source/drain regions 108L. The openings 159 may be formed using acceptable photolithography and etching techniques.

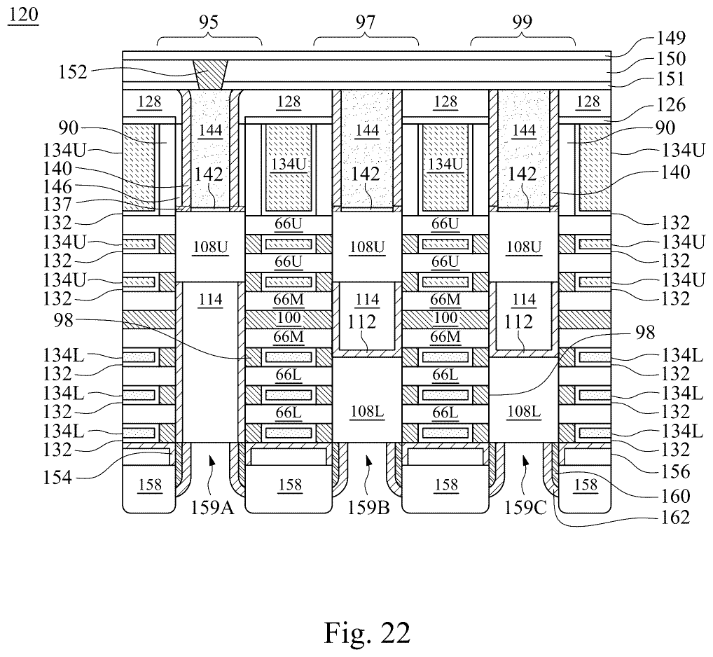

In FIG. 22, sacrificial spacers 160 may be formed on sidewalls of the openings 159 (e.g., the opening 159A, the opening 159B, and the opening 159C), such as on sidewalls of the ESL 154, and on portions of sidewalls of the ILD 158. The sacrificial spacers 160 may be formed using similar processes and similar materials as those described previously in FIGS. 13-14 for the formation of the sacrificial spacers 139. After the formation of the sacrificial spacers 160, spacers 162 are formed on the sacrificial spacers 160 in the openings 159 in the first region 95, the second region 97 and the third region 99. The spacers 162 may be formed using similar processes and similar materials as those described previously in FIG. 15 for the formation of the spacers 140.

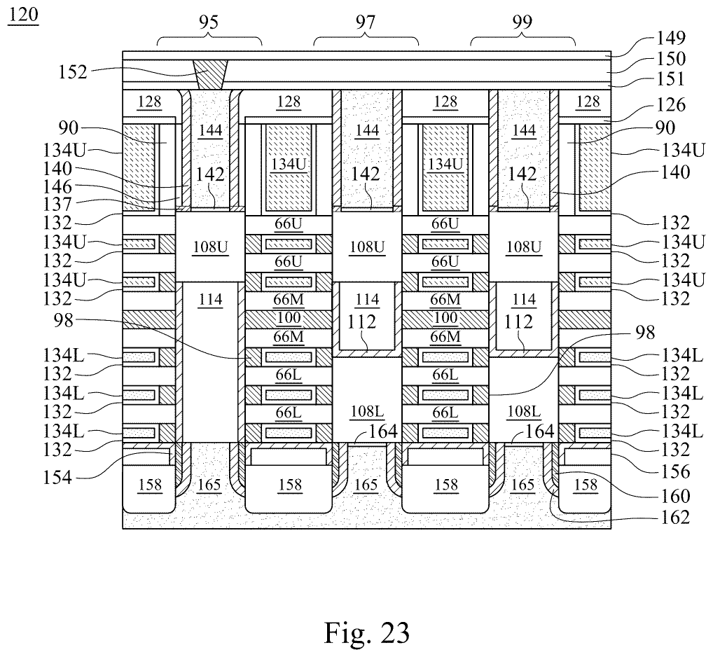

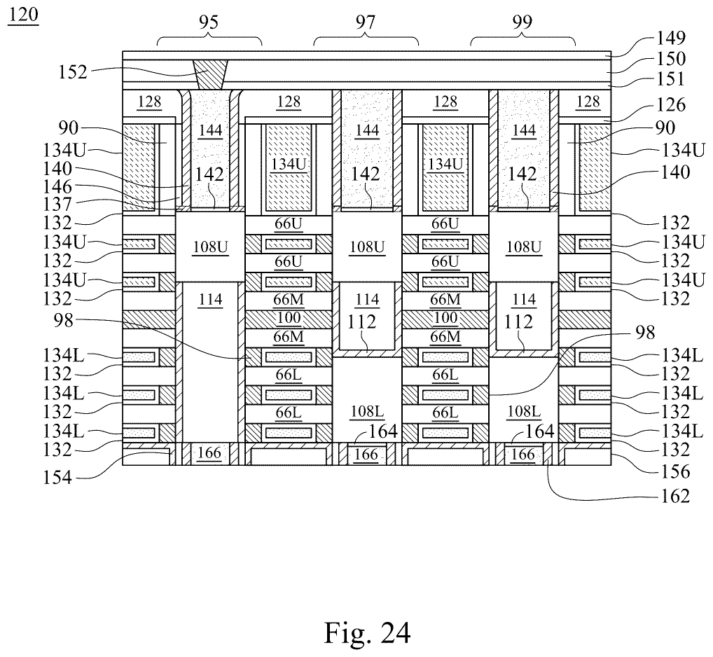

In FIGS. 23-24, metal contacts 166 are formed in the openings 159. For example, the metal contacts 166 may be formed to extend through the ILD 156 and the ESL 154 to electrically couple to the lower epitaxial source/drain regions 108L in the second region 97 and the third region 99. In FIG. 23, a liner (not separately illustrated), such as a diffusion barrier layer, an adhesion layer, or the like, and a conductive material 165 are formed in the openings 159 (e.g., the opening 159A, the opening 159B, and the opening 159C). The liner may include titanium, titanium nitride, tantalum, tantalum nitride, or the like. The conductive material 165 may be cobalt, tungsten, copper, a copper alloy, silver, gold, aluminum, nickel, or the like.

In FIG. 24, a planarization process such as a chemical mechanical polish (CMP) is performed to remove excess material of the liner and the conductive material 165 from top surfaces of the ILD 156 and the ESL 154. The remaining conductive material 165 and the liner in the openings 159 form the metal contacts 166. In an embodiment, the planarization process may also remove portions of the ILD 158, the sacrificial spacers 160, and the spacers 162 such that after the planarization process, top surfaces of the spacers 162, the sacrificial spacers 160, the ILD 156, the ESL 154, and the metal contacts 166 are substantially coplanar (within process variations). Optionally, metal-semiconductor alloy regions 164 are formed at the interfaces between the lower epitaxial source/drain regions 108L and the metal contacts 166. The metal-semiconductor alloy regions 164 may be formed using similar processes and similar materials as those described previously in FIG. 17 for the formation of the metal-semiconductor alloy regions 142.

Referring further to FIG. 24, the sacrificial spacers 160 in the first region 95, the second region 97, and the third region 99 are removed to form recesses between the spacers 162 and the ESL 154. The sacrificial spacers 160 may be removed using similar processes and etchants as those described previously in FIG. 18A to remove the sacrificial spacers 139. The recesses are adjacent the spacers 162, and are over the lower epitaxial source/drain regions 108L in the second region 97 and the third region 99. The recesses may also be over the first CESL 112 and/or the first ILD 114 in the first region 95. In an embodiment, the recesses surround the spacers 162 and the metal contacts 166 in each of the first region 95, the second region 97, and the third region 99.

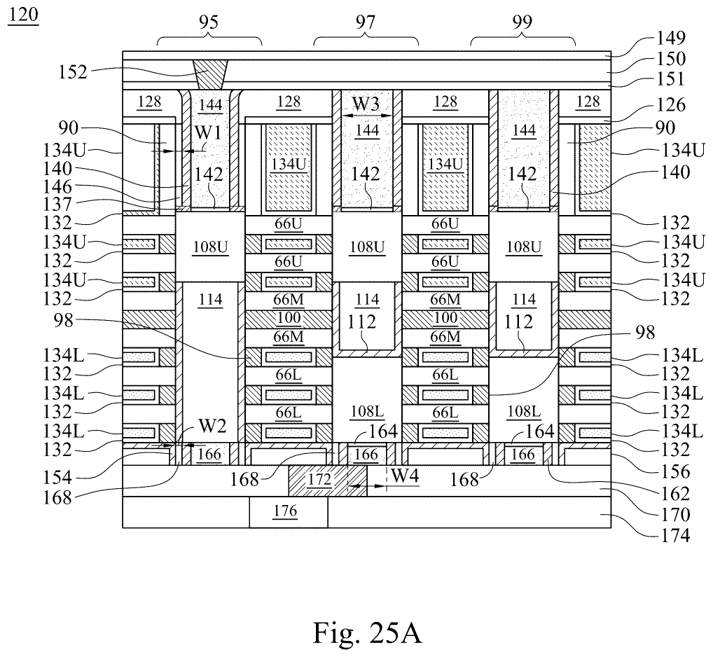

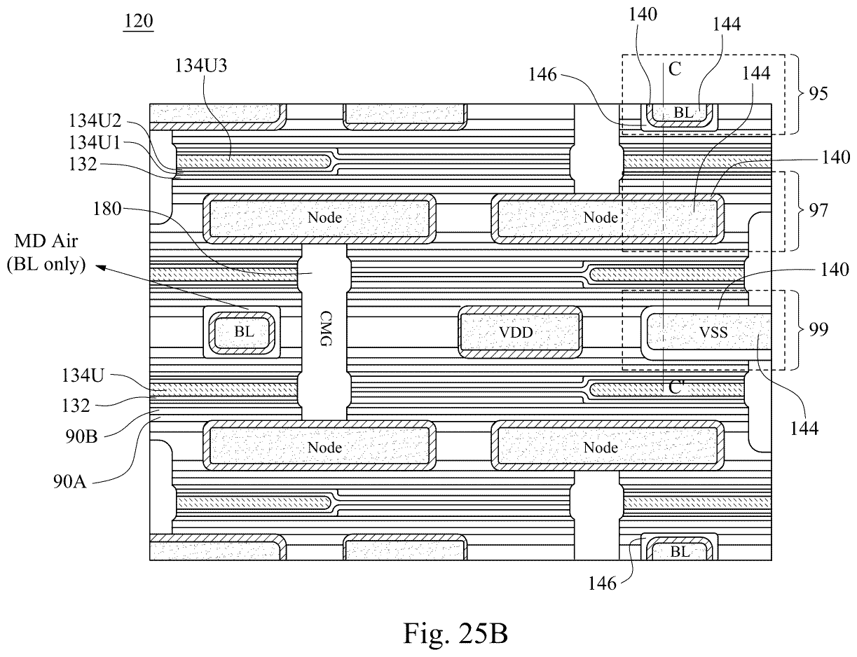

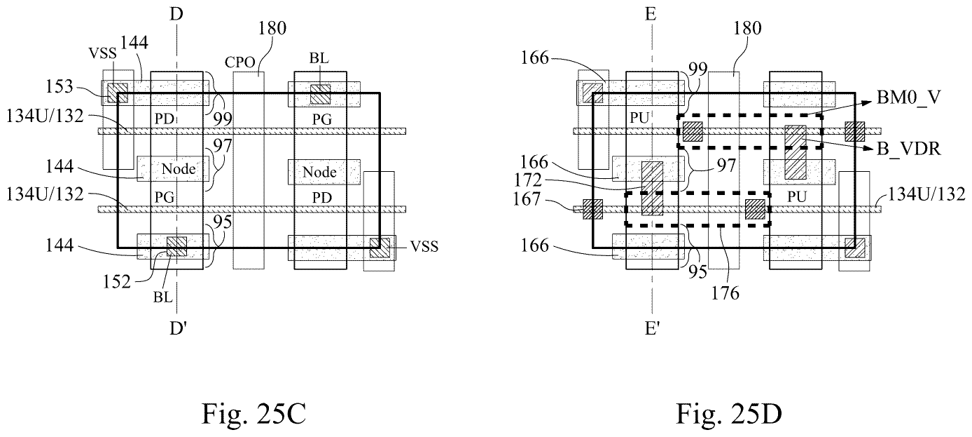

FIGS. 25A and 25C-25D illustrate the formation of an air-gap 168 that surrounds the spacers 162 and the metal contact 166 in each of the first region 95, the second region 97, and the third region 99. FIG. 25A illustrates a cross-sectional view along a line D-D′ shown in the FIG. 25C, and/or along a line E-E′ shown in the FIG. 25D. FIG. 25C illustrates a top-down view of the semiconductor device 120 that is shown in FIG. 25A. FIG. 25D illustrates a bottom-up view of the semiconductor device 120 that is shown in FIG. 25A. FIG. 25B illustrates a top-down view of the semiconductor device 120 having a plurality of gate spacers and a plurality of gate electrode layers, in accordance with other embodiments. In FIG. 25A, a dielectric layer 170 may be deposited over the backside of the semiconductor device 120, such as over the spacers 162, the ILD 156, the ESL 154, and the metal contacts 166. Forming the dielectric layer 170 results in the sealing of the recesses between the spacers 162 and ESL 154 in the first region 95, the second region 97, and the third region 99. In this way, the air-gap 168 is formed that surrounds the spacers 162 and the metal contact 166 in each of the first region 95, the second region 97, and the third region 99. The dielectric layer 170 may be formed of any suitable dielectric material, such as silicon nitride, silicon oxide, or the like, which may be formed by a deposition process, such as CVD, ALD, or the like. In an embodiment, a width W2 of each air-gap 168 may be in a range from 2 nm to 3 nm. In an embodiment, the metal contacts 144 in the second region 97 and the third region 99 may have a width W3, and the metal contacts 166 in each of the first region 95, the second region 97, and the third region 99 may have a width W4, wherein the width W4 is smaller than the width W3.

After the formation of the dielectric layer 170, a conductive line 172 may be formed in the dielectric layer 170. The conductive line 172 may be a backside power rail, or the like, and may comprise a conductive strip that is electrically connected to the metal contact 166 in the second region 97. To form the conductive line 172, a trench may be formed in the dielectric layer 170. The trench may be formed using acceptable photolithography and etching techniques. The trench may then be filled with a conductive material using CVD, physical vapor deposition (PVD), electro-chemical plating (ECP), electroless plating, or the like. The conductive material may comprise a material such as Cu, Al, Ti, Ta, W, Pt, Ni, Cr, Ru, TiN, TaN, combinations thereof, multilayers thereof, or the like. Any excess conductive material may be removed by, for example, a planarization process such as a chemical mechanical polish (CMP) process.

After the formation of the dielectric layer 170 and the conductive line 172, a dielectric layer 174 may be deposited over the backside of the semiconductor device 120, such as over the dielectric layer 170 and the conductive line 172. The dielectric layer 174 may be formed of any suitable dielectric material, such as silicon nitride, silicon oxide, or the like, which may be formed by a deposition process, such as CVD, ALD, or the like. After the formation of the dielectric layer 174, a conductive line 176 may be formed in the dielectric layer 174. The conductive line 176 may comprise a conductive strip that is electrically connected to the metal contact 166 in the second region 97. To form the conductive line 176, a trench may be formed in the dielectric layer 174. The trench may be formed using acceptable photolithography and etching techniques. The trench may then be filled with a conductive material using CVD, physical vapor deposition (PVD), electro-chemical plating (ECP), electroless plating, or the like. The conductive material may comprise a material such as Cu, Al, Ti, Ta, W, Pt, Ni, Cr, Ru, TiN, TaN, combinations thereof, multilayers thereof, or the like. Any excess conductive material may be removed by, for example, a planarization process such as a chemical mechanical polish (CMP) process. In an embodiment, a sub-region of the first region 95 that is disposed within the PMOS portion of the SRAM cell may also be referred to subsequently as a dummy region of the semiconductor device 120. In an embodiment, a sub-region of the second region 97 that is disposed within the PMOS portion of the SRAM cell may also be referred to subsequently as a node region of the semiconductor device 120. In an embodiment, the metal contact 166 that is disposed in a sub-region of the third region 99 that is within the PMOS portion of the SRAM cell may be a voltage drain supply (VDD) contact (e.g., which may be electrically connected to sources of PMOS portions of the CFETs). The conductive lines 172 and 176 may be used to electrically couple the gate electrodes 134 to the metal contact 166 of the node region of the PMOS portion of the SRAM cell.

Advantages can be achieved by removing the sacrificial spacers 160 in the first region 95, the second region 97, and the third region 99 to form recesses between the spacers 162 and the ESL 154. The recesses are formed in the PMOS portion of the SRAM cell and are disposed adjacent to the spacers 162, wherein the recesses are over the lower epitaxial source/drain regions 108L in the second region 97 and the third region 99. The dielectric layer 170 may be deposited over the spacers 162, the ILD 156, the ESL 154, and the metal contacts 166 to seal the recesses and form the air-gaps 168 between the spacers 162 and the ESL 154 in the first region 95, the second region 97, and the third region 99. Each air-gap 168 may surround the spacers 162 and the metal contact 166 in each of the first region 95, the second region 97, and the third region 99. The metal contacts 144 in the second region 97 and the third region 99 may have the width W3, and the metal contacts 166 in each of the first region 95, the second region 97, and the third region 99 may have the width W4, wherein the width W4 is smaller than the width W3.

These advantages include that by forming the air-gaps 168 to surround the metal contact 166 in the second region 97 and the metal contact 166 in the third region 99 (e.g., the VDD contact in the PMOS portion of the SRAM cell), an improved match can be achieved between the device performance of the n-type nanostructure-FETs in the NMOS portion of the SRAM Cell and the device performance of the p-type nanostructure-FETs in the PMOS portion of the SRAM cell. This is due to the fact that when p-type nanostructure-FETs have similar dimensions as n-type nanostructure-FETs, the p-type nanostructure-FETs typically have better device performance than the n-type nanostructure-FETs. The use of the air-gaps 168 that surround the metal contact 166 in the second region 97 and the metal contact 166 in the third region 99 allows for the tuning of the width W4 of the metal contacts 166 in the second region 97 and the third region 99 to be smaller than the width W3 of the metal contacts 144 of the second region 97 and the third region 99. This modification of the metal contact 166 geometry influences the overall electrical characteristics of the p-type nanostructure-FETs in the PMOS portion of the SRAM cell and allows the tuning of the device performance of the p-type nanostructure-FETs to match the device performance of the n-type nanostructure-FETs in the NMOS portion of the SRAM Cell. As a result, SRAM cell operation can be optimized.

FIG. 25B illustrates a top-down view of the semiconductor device 120 that has a plurality of gate spacers and a plurality of gate electrode layers, in accordance with other embodiments. For example, gate spacers 90A and gate spacers 90B may be disposed on sidewalls of the gate structures 134U/132. The gate spacers 90A may comprise a first material that is different from a material of the gate spacers 90B. In an embodiment, upper gate electrodes 134U of the gate structures 134U/132 may include more than one gate electrode layer (e.g., a first gate electrode layer 134U1, a second gate electrode layer 134U2, and a third gate electrode layer 134U3) disposed over the gate dielectrics 132. In FIG. 25B, the PMOS portion of the SRAM cell is shown, wherein the air-gap 146 surrounds the metal contact 144 and the spacers 140 in the first region 95. The metal contact 144 in the first region 95 may also be referred to subsequently as the bit line contact. It can be seen that there are no air-gaps that surround the spacers 140 and the metal contact 144 in the second region 97 (e.g., the node region). It can also be seen that there are no air-gaps that surround the spacers 140 and the metal contact 144 in the third region 99. FIG. 25B also shows isolation structures 180 that may be used to electrically isolate portions of the gate structures 132/134U from each other. Each isolation structure 180 may be formed using suitable photolithography and etching techniques to form an opening between portions of the gate structures 132/134U, and then filling the opening with a dielectric material (e.g., silicon oxide, or the like).

FIG. 25C illustrates a top-down view of the semiconductor device 120 that is shown in FIG. 25A. FIG. 25C illustrates the CFETS of the NMOS portion of the SRAM cell. In various embodiments, these CFETs may include, for example, pull-down (PD) transistors disposed between the second region 97 and the third region 99, and pass-gate (PG) transistors disposed between the first region 95 and the second region 97. The metal contacts 144 are electrically connected to the upper epitaxial source/drain regions 108U in the first region 95, the second region 97, and the third region 99. For example, the metal contact 144 in the first region 95 may be referred to as a bit line contact, and may be used to electrically connect the bit line 149 (e.g., through the contact via 152) to drains of the pass-gate (PG) transistors to allow data to be read from or written to the SRAM cell. The metal contact 144 in the second region 97 may be electrically connected to the storage nodes of the SRAM cell. The metal contact 144 (which may also be referred to as a voltage source supply (VSS) contact) in the third region 99 may be electrically connected to the pull-down (PD) transistors of the SRAM cell. This connection allows the pull-down (PD) transistors to effectively pull the storage node to ground during write operations or when maintaining a logical ‘0’ state. FIG. 25C also shows isolation structure 180 that electrically isolates portions of the gate structures 134U/132. The metal contact 144 in the third region 99 may be electrically connected to other metal layers of the semiconductor device 120 through a contact via 153.

FIG. 25D illustrates a bottom-up view of the semiconductor device 120 that is shown in FIG. 25A. FIG. 25D illustrates the CFETs of the PMOS portion of the SRAM cell. In various embodiments, these CFETs may include, for example, pull-up (PU) transistors that are disposed between the second region 97 and the third region 99. The metal contacts 166 are electrically connected to the lower epitaxial source/drain regions 108L in the second region 97 and the third region 99. For example, the metal contact 166 in the first region 95 may be referred to as a dummy contact. The metal contact 166 in the second region 97 may be electrically connected to the storage nodes of the SRAM cell. The metal contact 166 (which may also be referred to as voltage drain supply (VDD) contact) in the third region 99 may be electrically connected to the source regions of the pull-up (PU) transistors of the SRAM cell. This connection may provide the positive supply voltage necessary for the pull-up (PU) transistors to pull the storage node to a high state when required. FIG. 25D also shows the isolation structure 180 that electrically isolates portions of the gate structures 134U/132.

FIG. 25D also shows the conductive lines 172 and 176, which may be used to electrically couple the gate electrodes 134 to the metal contacts 166 in the node region (e.g., that is disposed within the second region 97) of the PMOS portion of the SRAM cell through a contact via 167. In an embodiment, the conductive lines 172 and 176 may also facilitate coupling of the lower gate electrode 134L and the upper gate electrode 134U, and in this way provide connections between the PMOS portion of the SRAM cell and the NMOS portion of the SRAM cell.

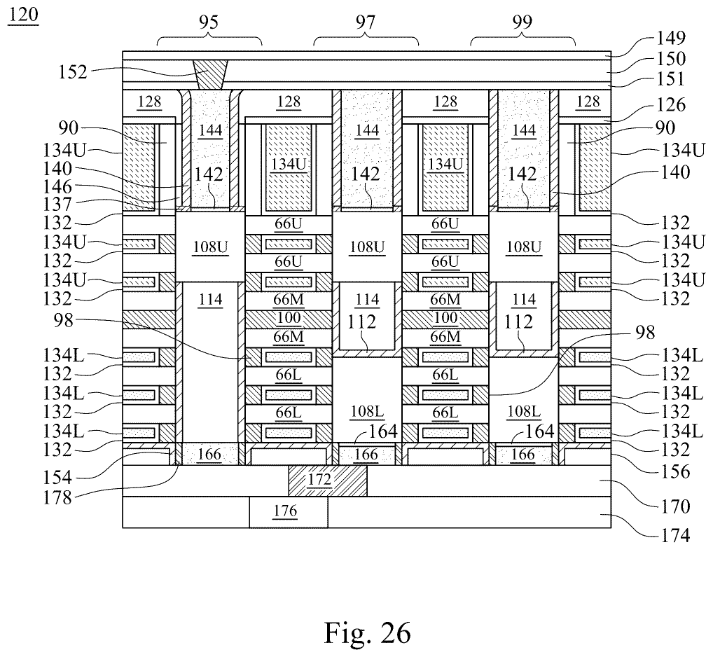

FIG. 26 illustrates the semiconductor device 120 in accordance with some other embodiments. Unless specified otherwise, like reference numerals in this embodiment represent like components in the embodiment shown in FIGS. 1 through 25D formed by like processes. Accordingly, the process steps and applicable materials may not be repeated herein.

The embodiment illustrated in FIG. 26 may be similar to the embodiment illustrated in FIG. 25A, except that in the embodiment illustrated in FIG. 26, no air-gap 168 is formed to surround the metal contact 166 in each of the first region 95, the second region 97, and the third region 99. As such, the absence of the air-gaps 168 will result in sidewalls of the metal contacts 166 being in physical contact with materials of the surrounding elements, such as, for example, an ESL 178, or the like. The ESL 178 may comprise a dielectric material such as, silicon nitride, silicon oxide, silicon oxynitride, or the like. However, the air-gap 146 (described previously in FIGS. 1-25D) that surrounds portions of the spacers 140 and the metal contact 144 in the first region 95 is present in the embodiment shown in FIG. 26.

The embodiments of the present disclosure have some advantageous features. The embodiments include forming an air-gap to surround a bit line contact (e.g., which is electrically connected to a bit line) in a bit line region of a NMOS portion of an SRAM cell. The NMOS portion of the SRAM cell may be a region of the SRAM cell that comprises NMOS portions of CFETs. A PMOS portion of the SRAM cell may be a region of the SRAM cell that comprises PMOS portions of the CFETs. No air-gap is formed to surround a first node contact (e.g., which is electrically connected to an internal storage node) in a node region of the NMOS portion of the SRAM cell, and no air-gap is formed to surround a voltage source supply (VSS) contact (e.g., which may be electrically connected to sources of NMOS portions of the CFETs) in a first region of the NMOS portion of the SRAM cell. The air-gap may be formed by first depositing a sacrificial silicon layer. The sacrificial silicon layer is then selectively removed to leave a space where the sacrificial silicon layer was previously disposed. In addition, an air-gap may be formed to surround a second node contact (e.g., which may be electrically connected to the internal storage node) in a node region of the PMOS portion of the SRAM cell, and an air-gap may be formed to surround a voltage drain supply (VDD) contact (e.g., which may be electrically connected to sources of PMOS portions of the CFETs) in a first region of the PMOS portion of the SRAM cell.

One or more embodiments disclosed herein may allow for a reduction of the capacitance associated with the bit line contact. As a result, total capacitance of the bit line of the SRAM cell can be reduced, and less charge may be required to change the bit line voltage during read and write operations. This leads to quicker read and write operations in the SRAM cell. As a result, the speed of the SRAM cell operations can be increased. In addition, due to no air-gap being formed to surround each of the first node contact and the VSS contact in the NMOS portion of the SRAM cell, the VSS contact and the first node contact can be formed having larger dimensions (e.g., larger widths) as there is no need to accommodate the space that would be occupied by the air-gap. The increased dimensions of the first node contact and the VSS contact lead to lower electrical resistances through these contacts, and as a result, SRAM cell performance can be improved. Further, by selectively adding air-gaps to surround each of the second node contact and the VDD contact in the PMOS portion of the SRAM cell, an improved match can be achieved between the device performance of the n-type nanostructure-FETs in the NMOS portion of the CFETs and the device performance of the p-type nanostructure-FETs in the PMOS portion of the CFETs.

In accordance with an embodiment, a semiconductor device includes a plurality of first nanostructures, the plurality of first nanostructures extending between first source/drain regions; a plurality of second nanostructures over the plurality of first nanostructures, the plurality of second nanostructures extending between second source/drain regions; a first gate stack around the plurality of first nanostructures; a second gate stack over the first gate stack and disposed around the plurality of second nanostructures, where a first portion of the second gate stack is disposed above the plurality of second nanostructures; gate spacers on sidewalls of the first portion of the second gate stack; and a first metal contact extending between a first gate spacer of the gate spacers and a second gate spacer of the gate spacers to physically contact a first source/drain region of the second source/drain regions, where an air-gap is disposed between a sidewall of the first metal contact and a sidewall of the first gate spacer. In an embodiment, the semiconductor device is a memory device, and where the semiconductor device further includes a bit line over and electrically connected to the first metal contact. In an embodiment, the semiconductor device further includes a first spacer layer on sidewalls of the first metal contact, where the first spacer layer surrounds the first metal contact. In an embodiment, the air-gap is disposed between the first spacer layer and the sidewall of the first gate spacer. In an embodiment, the air-gap has a width that is in a range from 2 nm to 3 nm. In an embodiment, the air-gap surrounds the first metal contact and the first spacer layer. In an embodiment, the semiconductor device further includes a second metal contact extending between a third gate spacer of the gate spacers and a fourth gate spacer of the gate spacers to physically contact a second source/drain region of the second source/drain regions, where no air-gap is disposed between a sidewall of the second metal contact and a sidewall of the third gate spacer; and a second spacer layer on sidewalls of the second metal contact, where the second spacer layer surrounds the second metal contact, and where the second spacer layer is in physical contact with the third gate spacer and the fourth gate spacer. In an embodiment, the second metal contact is electrically connected to a storage node.

In accordance with an embodiment, a semiconductor device includes a plurality of first nanostructures, the plurality of first nanostructures extending between first source/drain regions; a plurality of second nanostructures over the plurality of first nanostructures, the plurality of second nanostructures extending between second source/drain regions; a first gate stack around the plurality of first nanostructures; a second gate stack over the first gate stack and disposed around the plurality of second nanostructures, where a first portion of the second gate stack is disposed above the plurality of second nanostructures; gate spacers on sidewalls of the first portion of the second gate stack; a first inter-layer dielectric (ILD) on a backside of the first gate stack; a first metal contact extending through the first portion of the second gate stack and between a first gate spacer of the gate spacers and a second gate spacer of the gate spacers to physically contact a first source/drain region of the second source/drain regions, where a first air-gap is disposed between a sidewall of the first metal contact and a sidewall of the first gate spacer; and a first backside metal contact extending through the first ILD to physically contact a first source/drain region of the first source/drain regions, where a second air-gap is disposed between a sidewall of the first backside metal contact and a sidewall of the first ILD. In an embodiment, the semiconductor device further includes a second metal contact extending through the first portion of the second gate stack and between a third gate spacer of the gate spacers and a fourth gate spacer of the gate spacers to physically contact a second source/drain region of the second source/drain regions; and a first spacer layer on sidewalls of the second metal contact, where the first spacer layer surrounds the second metal contact, and where the first spacer layer is in physical contact with the third gate spacer and the fourth gate spacer. In an embodiment, the second metal contact overlaps the first backside metal contact. In an embodiment, a width of the first backside metal contact is smaller than a width of the second metal contact. In an embodiment, a width of the first air-gap is in a range from 2 nm to 3 nm. In an embodiment, the first air-gap surrounds the first metal contact. In an embodiment, the semiconductor device further includes a bit line over and electrically connected to the first metal contact.

In accordance with an embodiment, a method includes forming a multi-layer stack over a semiconductor substrate, the multi-layer stack including alternating semiconductor nanostructures and dummy nanostructures; forming lower source/drain regions, where lower semiconductor nanostructures of the semiconductor nanostructures extend between the lower source/drain regions; forming upper source/drain regions over the lower source/drain regions, where upper semiconductor nanostructures of the semiconductor nanostructures extend between the upper source/drain regions; replacing the dummy nanostructures with a lower gate stack around the lower semiconductor nanostructures and an upper gate stack around the upper semiconductor nanostructures, where a first portion of the upper gate stack is disposed above the upper semiconductor nanostructures, and where gate spacers are disposed on sidewalls of the first portion of the upper gate stack; and forming a first metal contact that extends through the first portion of the upper gate stack and between a first gate spacer of the gate spacers and a second gate spacer of the gate spacers to physically contact a first upper source/drain region of the upper source/drain regions, where an air-gap is disposed between a sidewall of the first metal contact and a sidewall of the first gate spacer. In an embodiment, the method further includes forming a bit line over and electrically connected to the first metal contact. In an embodiment, the method further includes forming a first spacer layer on sidewalls of the first metal contact, where the first spacer layer surrounds the first metal contact, where the air-gap surrounds the first spacer layer and the first metal contact, and where the air-gap has a width that is in a range from 2 nm to 3 nm. In an embodiment, the method further includes forming a second metal contact that extends through the first portion of the upper gate stack and between a third gate spacer of the gate spacers and a fourth gate spacer of the gate spacers to physically contact a second upper source/drain region of the upper source/drain regions; and forming a second spacer layer on sidewalls of the second metal contact, where the second spacer layer surrounds the second metal contact, and where the second spacer layer is in physical contact with the third gate spacer and the fourth gate spacer. In an embodiment, the method further includes forming a third metal contact that extends through the first portion of the upper gate stack and between a fifth gate spacer of the gate spacers and a sixth gate spacer of the gate spacers to physically contact a third upper source/drain region of the upper source/drain regions; and forming a third spacer layer on sidewalls of the third metal contact, where the third spacer layer surrounds the third metal contact, and where the third spacer layer is in physical contact with the fifth gate spacer and the sixth gate spacer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a plurality of first nanostructures, the plurality of first nanostructures extending between first source/drain regions;
a plurality of second nanostructures over the plurality of first nanostructures, the plurality of second nanostructures extending between second source/drain regions;
a first gate stack around the plurality of first nanostructures;
a second gate stack over the first gate stack and disposed around the plurality of second nanostructures, wherein a first portion of the second gate stack is disposed above the plurality of second nanostructures;
gate spacers on sidewalls of the first portion of the second gate stack; and
a first metal contact extending between a first gate spacer of the gate spacers and a second gate spacer of the gate spacers to physically contact a first source/drain region of the second source/drain regions, wherein an air-gap is disposed between a sidewall of the first metal contact and a sidewall of the first gate spacer.

2. The semiconductor device of claim 1, wherein the semiconductor device is a memory device, and wherein the semiconductor device further comprises a bit line over and electrically connected to the first metal contact.

3. The semiconductor device of claim 1, further comprising:
a first spacer layer on sidewalls of the first metal contact, wherein the first spacer layer surrounds the first metal contact.

4. The semiconductor device of claim 3, wherein the air-gap is disposed between the first spacer layer and the sidewall of the first gate spacer.

5. The semiconductor device of claim 4, wherein the air-gap has a width that is in a range from 2 nm to 3 nm.

6. The semiconductor device of claim 5, wherein the air-gap surrounds the first metal contact and the first spacer layer.

7. The semiconductor device of claim 1, further comprising:
a second metal contact extending between a third gate spacer of the gate spacers and a fourth gate spacer of the gate spacers to physically contact a second source/drain region of the second source/drain regions, wherein no air-gap is disposed between a sidewall of the second metal contact and a sidewall of the third gate spacer; and
a second spacer layer on sidewalls of the second metal contact, wherein the second spacer layer surrounds the second metal contact, and wherein the second spacer layer is in physical contact with the third gate spacer and the fourth gate spacer.

8. The semiconductor device of claim 7, wherein the second metal contact is electrically connected to a storage node.

9. A semiconductor device comprising:
a plurality of first nanostructures, the plurality of first nanostructures extending between first source/drain regions;
a plurality of second nanostructures over the plurality of first nanostructures, the plurality of second nanostructures extending between second source/drain regions;
a first gate stack around the plurality of first nanostructures;
a second gate stack over the first gate stack and disposed around the plurality of second nanostructures, wherein a first portion of the second gate stack is disposed above the plurality of second nanostructures;
gate spacers on sidewalls of the first portion of the second gate stack;
a first inter-layer dielectric (ILD) on a backside of the first gate stack;
a first metal contact extending through the first portion of the second gate stack and between a first gate spacer of the gate spacers and a second gate spacer of the gate spacers to physically contact a first source/drain region of the second source/drain regions, wherein a first air-gap is disposed between a sidewall of the first metal contact and a sidewall of the first gate spacer; and
a first backside metal contact extending through the first ILD to physically contact a first source/drain region of the first source/drain regions, wherein a second air-gap is disposed between a sidewall of the first backside metal contact and a sidewall of the first ILD.

10. The semiconductor device of claim 9, further comprising:
a second metal contact extending through the first portion of the second gate stack and between a third gate spacer of the gate spacers and a fourth gate spacer of the gate spacers to physically contact a second source/drain region of the second source/drain regions; and
a first spacer layer on sidewalls of the second metal contact, wherein the first spacer layer surrounds the second metal contact, and wherein the first spacer layer is in physical contact with the third gate spacer and the fourth gate spacer.

11. The semiconductor device of claim 10, wherein the second metal contact overlaps the first backside metal contact.

12. The semiconductor device of claim 11, wherein a width of the first backside metal contact is smaller than a width of the second metal contact.

13. The semiconductor device of claim 9, wherein a width of the first air-gap is in a range from 2 nm to 3 nm.

14. The semiconductor device of claim 13, wherein the first air-gap surrounds the first metal contact.

15. The semiconductor device of claim 14, further comprising a bit line over and electrically connected to the first metal contact.

16. A method comprising:
forming a multi-layer stack over a semiconductor substrate, the multi-layer stack comprising alternating semiconductor nanostructures and dummy nanostructures;
forming lower source/drain regions, wherein lower semiconductor nanostructures of the semiconductor nanostructures extend between the lower source/drain regions;
forming upper source/drain regions over the lower source/drain regions, wherein upper semiconductor nanostructures of the semiconductor nanostructures extend between the upper source/drain regions;
replacing the dummy nanostructures with a lower gate stack around the lower semiconductor nanostructures and an upper gate stack around the upper semiconductor nanostructures, wherein a first portion of the upper gate stack is disposed above the upper semiconductor nanostructures, and wherein gate spacers are disposed on sidewalls of the first portion of the upper gate stack; and
forming a first metal contact that extends through the first portion of the upper gate stack and between a first gate spacer of the gate spacers and a second gate spacer of the gate spacers to physically contact a first upper source/drain region of the upper source/drain regions, wherein an air-gap is disposed between a sidewall of the first metal contact and a sidewall of the first gate spacer.

17. The method of claim 16, further comprising:
forming a bit line over and electrically connected to the first metal contact.

18. The method of claim 16, further comprising:
forming a first spacer layer on sidewalls of the first metal contact, wherein the first spacer layer surrounds the first metal contact, wherein the air-gap surrounds the first spacer layer and the first metal contact, and wherein the air-gap has a width that is in a range from 2 nm to 3 nm.

19. The method of claim 16, further comprising:
forming a second metal contact that extends through the first portion of the upper gate stack and between a third gate spacer of the gate spacers and a fourth gate spacer of the gate spacers to physically contact a second upper source/drain region of the upper source/drain regions; and
forming a second spacer layer on sidewalls of the second metal contact, wherein the second spacer layer surrounds the second metal contact, and wherein the second spacer layer is in physical contact with the third gate spacer and the fourth gate spacer.

20. The method of claim 19, further comprising:
forming a third metal contact that extends through the first portion of the upper gate stack and between a fifth gate spacer of the gate spacers and a sixth gate spacer of the gate spacers to physically contact a third upper source/drain region of the upper source/drain regions; and
forming a third spacer layer on sidewalls of the third metal contact, wherein the third spacer layer surrounds the third metal contact, and wherein the third spacer layer is in physical contact with the fifth gate spacer and the sixth gate spacer.
